(19) United States
(12) Patent Application Publication
(10) Pub. No.: US 2026/0032973 A1
(43) Pub. Date: Jan. 29, 2026

(54) GATE TRENCH POWER SEMICONDUCTOR DEVICES HAVING SHALLOW TRENCH SHIELDS AND DEEP SUPPORT SHIELDS

(71) Applicant: Wolfspeed, Inc., Durham, NC (US)

(72) Inventors: Woongsun Kim, Cary, NC (US); Naeem Islam, Fuquay-Varina, NC (US); Madankumar Sampath, Morrisville, NC (US); Sei-Hyung Ryu, Cary, NC (US); Ping-Ju Chuang, Morrisville, NC (US)

(21) Appl. No.: 19/014,347

(22) Filed: Jan. 9, 2025

Related U.S. Application Data
(63) Continuation-in-part of application No. 18/780,825, filed on Jul. 23, 2024.

(51) Int. Cl. H10D 62/10; H10D 30/66; H10D 62/832

(52) U.S. Cl. CPC H10D 62/107; H10D 30/668; H10D 62/125; H10D 62/8325

(57) ABSTRACT

A gate-controlled semiconductor device comprises a semiconductor layer structure and a gate trench in the semiconductor layer structure. The semiconductor layer structure comprises a drift region that has a first conductivity type, a trench shield that has a second conductivity type underneath the gate trench, and a support shield that has the second conductivity type extending toward a lower surface of the semiconductor layer structure. The support shield has a peak doping concentration at a first depth from the upper surface of the semiconductor layer structure. A lowermost portion of the trench shield is at a second depth from the upper surface of the semiconductor layer structure that is less than the first depth, and a thickness of the trench shield is less than the first depth minus the second depth.

### CROSS-REFERENCE TO RELATED APPLICATIONS

This application is a continuation-in-part of U.S. patent application Ser. No. 18/780,825, filed on Jul. 23, 2024, the disclosure of which is hereby incorporated herein by reference in its entirety.

### FIELD OF THE INVENTION

The present invention relates to power semiconductor devices and, more particularly, to gate trench power semiconductor devices that include support shields.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure and are separated by a channel region. A gate electrode is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type conductivity, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In many applications, MOSFETs may need to carry large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power MOSFETs and other power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure).

The semiconductor layer structure of a power semiconductor device includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes. Gate trench devices may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

Pursuant to some embodiments of the present invention, gate-controlled semiconductor devices are provided that comprise a semiconductor layer structure having an upper surface and a lower surface that are spaced apart from each other in a depth direction and a gate trench in the semiconductor layer structure. The semiconductor layer structure comprises a drift region that has a first conductivity type, a trench shield that has a second conductivity type, the trench shield underneath the gate trench, and a support shield that has the second conductivity type extending toward the lower surface of the semiconductor layer structure. The support shield has a peak doping concentration at a first depth from the upper surface of the semiconductor layer structure, a lowermost portion of the trench shield is at a second depth from the upper surface of the semiconductor layer structure that is less than the first depth, and the thickness of the trench shield in the depth direction is less than the first depth minus the second depth.

In some embodiments, the trench shield has a peak doping concentration at a third depth from the upper surface of the semiconductor layer structure, and a thickness of the trench shield in the depth direction is less than the first depth minus the third depth.

In some embodiments, a peak doping concentration of the trench shield and the peak doping concentration of the support shield differ by no more than a factor of three.

In some embodiments, the thickness of the trench shield is less than 0.3 microns.

In some embodiments, a peak doping concentration of the trench shield is at a depth of between 0.6 and 1.1 microns from the upper surface of the semiconductor layer structure.

In some embodiments, an upper portion of the drift region comprises a JFET region that has the first conductivity type and a peak doping concentration that is at least an order of magnitude greater than a peak doping concentration of a lower portion of the drift region. In some embodiments, a peak doping concentration of the trench shield is less than two orders of magnitude greater than the peak doping of the concentration of the JFET region. In some embodiments, a lowermost portion of the JFET region is at a fourth depth from the upper surface of the semiconductor layer structure that is deeper than the second depth. In some embodiments, a lowermost portion of the support shield is at a fifth depth from the upper surface of the semiconductor layer structure that is deeper than the fourth depth.

In some embodiments, the gate trench is a first gate trench and the gate-controlled semiconductor device further comprises a second gate trench in the semiconductor layer structure, and the support shield is positioned midway between the first and second gate trenches.

In some embodiments, the lower surface of the semiconductor layer structure and a segment extending between a point on a sidewall of the support shield that is at the first depth and a point on a facing sidewall of the trench shield that is at the third depth defines an angle of at least 30°.

In some embodiments, a lowermost portion of the support shield is at a fifth depth from the upper surface of the semiconductor layer structure that is more than three times greater than a minimum lateral distance between a sidewall of the trench shield and a facing sidewall of the support shield.

In some embodiments, the lower surface of the semiconductor layer structure and a segment extending between a point on a sidewall of the support shield that is closest in the lateral direction to the trench shield and a point on a facing sidewall of the trench shield that is at a third depth from the upper surface of the semiconductor layer structure where the trench shield has a peak doping concentration defines an angle of at least 20°.

In some embodiments, the semiconductor layer structure further comprises a well region that has the second conductivity type on the drift region, the well region comprising a channel region adjacent the gate trench. In some embodiments, a difference between a maximum depth of the support shield from the upper surface of the semiconductor layer structure and a maximum depth of the channel region from the upper surface of the semiconductor layer structure is more than five times the thickness of the trench shield in the depth direction.

In some embodiments, a peak doping concentration of the trench shield is within 0.1 microns of an uppermost surface of the trench shield.

Pursuant to further embodiments of the present invention, gate-controlled semiconductor devices are provided that comprise a semiconductor layer structure having an upper surface and a lower surface that are spaced apart from each other in a depth direction and a gate trench in the semiconductor layer structure. The semiconductor layer structure comprises a drift region that has a first conductivity type, a trench shield that has a second conductivity type, the trench shield underneath the gate trench, and a support shield that has the second conductivity type extending toward the lower surface of the semiconductor layer structure. The lower surface of the semiconductor layer structure and a segment extending between a point on a sidewall of the support shield that is at a first depth from the upper surface of the semiconductor layer structure where the support shield has a peak doping concentration and a point on a facing sidewall of the trench shield that is at a third depth from the upper surface of the semiconductor layer structure where the trench shield has a peak doping concentration defines an angle of at least 30°.

In some embodiments, a lowermost portion of the trench shield is at a second depth from the upper surface of the semiconductor layer structure that is less than the first depth, and a thickness of the trench shield in the depth direction is less than the first depth minus the second depth.

In some embodiments, a thickness of the trench shield in the depth direction is less than the first depth minus the third depth.

In some embodiments, the peak doping concentration of the trench shield and the peak doping concentration of the support shield differ by no more than a factor of three.

In some embodiments, a thickness of the trench shield is less than 0.3 microns.

In some embodiments, the peak doping concentration of the trench shield is at a depth of between 0.6 and 1.1 microns from the upper surface of the semiconductor layer structure.

In some embodiments, an upper portion of the drift region comprises a JFET region that has the first conductivity type and a peak doping concentration that is at least an order of magnitude greater than a peak doping concentration of a lower portion of the drift region.

In some embodiments, a peak doping concentration of the trench shield is less than two orders of magnitude greater than the peak doping of the concentration of the JFET region.

In some embodiments, a lowermost portion of the JFET region is at a fourth depth from the upper surface of the semiconductor layer structure that is deeper than the second depth. In some embodiments, a lowermost portion of the support shield is at a fifth depth from the upper surface of the semiconductor layer structure that is deeper than the fourth depth.

In some embodiments, the gate trench is a first gate trench and the gate-controlled semiconductor device further comprises a second gate trench in the semiconductor layer structure, and the support shield is positioned midway between the first and second gate trenches.

In some embodiments, a maximum depth of the support shield into the semiconductor layer structure is more than three times greater than a minimum lateral distance between a sidewall of the trench shield and a facing sidewall of the support shield.

In some embodiments, the semiconductor layer structure further comprises a well region that has the second conductivity type on the drift region, the well region comprising a channel region adjacent the gate trench. In some embodiments, a difference between a maximum depth of the support shield from the upper surface of the semiconductor layer structure and a maximum depth of the channel region from the upper surface of the semiconductor layer structure is more than five times a thickness of the trench shield in the depth direction.

In some embodiments, the peak doping concentration of the trench shield is within 0.1 microns of an uppermost surface of the trench shield.

Pursuant to additional embodiments of the present invention, gate-controlled semiconductor devices are provided that comprise a semiconductor layer structure having an upper surface and a lower surface that are spaced apart from each other in a depth direction and a gate trench in the semiconductor layer structure. The semiconductor layer structure comprises a drift region that has a first conductivity type, a trench shield that has a second conductivity type, the trench shield underneath the gate trench, and a support shield that has the second conductivity type extending toward the lower surface of the semiconductor layer structure. A lowermost portion of the JFET region is closer to the lower surface of the semiconductor layer structure than a lowermost portion of the trench shield, and the support shield extends deeper into the semiconductor layer structure than the JFET region.

In some embodiments, the lowermost portion of the JFET region is at a fourth depth from the upper surface of the semiconductor layer structure that is greater than a first depth from the upper surface of the semiconductor layer structure where the support shield has a peak doping concentration.

In some embodiments, a peak doping concentration of the trench shield and a peak doping concentration of the support shield differ by no more than a factor of three.

In some embodiments, a thickness of the trench shield is less than 0.3 microns.

In some embodiments, a peak doping concentration of the trench shield is at a depth of between 0.6 and 1.1 microns from the upper surface of the semiconductor layer structure.

In some embodiments, a peak doping concentration of the JFET region is at least an order of magnitude greater than the peak doping concentration of the drift region. In some embodiments, the lowermost portion of the JFET region is at a fourth depth from the upper surface of the semiconductor layer structure that is deeper than a second depth of a lowermost portion of the trench shield in the semiconductor layer structure. In some embodiments, a lowermost portion of the support shield is at a fifth depth from the upper surface of the semiconductor layer structure that is deeper than the fourth depth. In some embodiments, a peak doping concentration of the trench shield is less than two orders of magnitude greater than the peak doping of the concentration of the JFET region.

In some embodiments, the gate trench is a first gate trench and the gate-controlled semiconductor device further comprises a second gate trench in the semiconductor layer structure, and the support shield is positioned midway between the first and second gate trenches.

In some embodiments, the support shield has a peak doping concentration at a first depth from the upper surface of the semiconductor layer structure, wherein a lowermost portion of the trench shield is at a second depth from the upper surface of the semiconductor layer structure that is less than the first depth, and wherein a thickness of the trench shield in the depth direction is less than the first depth minus the second depth.

In some embodiments, the lower surface of the semiconductor layer structure and a segment extending between a point on a sidewall of the support shield that is closest in the lateral direction to the trench shield and a point on a facing sidewall of the trench shield that is at a third depth from the upper surface of the semiconductor layer structure where the trench shield has a peak doping concentration defines an angle of at least 20°.

In some embodiments, a maximum depth of the support shield into the semiconductor layer structure is more than three times greater than a minimum lateral distance between a sidewall of the trench shield and a facing sidewall of the support shield.

In some embodiments, a peak doping concentration of the trench shield is within 0.1 microns of an uppermost surface of the trench shield.

Pursuant to other embodiments of the present invention, gate-controlled semiconductor devices are provided that comprise a semiconductor layer structure having an upper surface and a lower surface that are spaced apart from each other in a depth direction and a gate trench in the semiconductor layer structure. The semiconductor layer structure comprises a drift region that has a first conductivity type, a trench shield that has a second conductivity type, the trench shield underneath the gate trench, and a support shield that has the second conductivity type extending toward the lower surface of the semiconductor layer structure. A maximum depth of the support shield into the semiconductor layer structure is more than three times greater than a minimum lateral distance between a sidewall of the trench shield and a facing sidewall of the support shield.

In some embodiments, a peak doping concentration of the trench shield and a peak doping concentration of the support shield differ by no more than a factor of three.

In some embodiments, a thickness of the trench shield is less than 0.3 microns.

In some embodiments, a peak doping concentration of the trench shield is at a depth of between 0.6 and 1.1 microns from the upper surface of the semiconductor layer structure.

In some embodiments, an upper portion of the drift region comprises a JFET region that has the first conductivity type and a peak doping concentration that is at least an order of magnitude greater than a peak doping concentration of a lower portion of the drift region. In some embodiments, a lowermost portion of the JFET region is at a fourth depth from the upper surface of the semiconductor layer structure that is deeper than the second depth, and a lowermost portion of the support shield is at a fifth depth from the upper surface of the semiconductor layer structure that is deeper than the fourth depth.

In some embodiments, the gate trench is a first gate trench and the gate-controlled semiconductor device further comprises a second gate trench in the semiconductor layer structure, and the support shield is positioned midway between the first and second gate trenches.

In some embodiments, the support shield has a peak doping concentration at a first depth from the upper surface of the semiconductor layer structure, wherein a lowermost portion of the trench shield is at a second depth from the upper surface of the semiconductor layer structure that is less than the first depth, and wherein a thickness of the trench shield in the depth direction is less than the first depth minus the second depth.

In some embodiments, the lower surface of the semiconductor layer structure and a segment extending between a point on the facing sidewall of the support shield that is at a first depth from the upper surface of the semiconductor layer structure where the support shield has a peak doping concentration and a point on the sidewall of the trench shield that is at a third depth from the upper surface of the semiconductor layer structure where the trench shield has a peak doping concentration defines an angle of at least 30°.

In some embodiments, a difference between the maximum depth of the support shield from the upper surface of the semiconductor layer structure and a maximum depth of the channel region from the upper surface of the semiconductor layer structure is more than five times a thickness of the trench shield in the depth direction.

In some embodiments, a peak doping concentration of the trench shield is within 0.1 microns of an uppermost surface of the trench shield.

Pursuant to still further embodiments of the present invention, gate-controlled semiconductor devices are provided that comprise a semiconductor layer structure having an upper surface and a lower surface that are spaced apart from each other in a depth direction and a gate trench in the semiconductor layer structure. The semiconductor layer structure comprises a drift region that has a first conductivity type, a trench shield that has a second conductivity type, the trench shield underneath the gate trench, and a support shield that has the second conductivity type extending toward the lower surface of the semiconductor layer structure. The lower surface of the semiconductor layer structure and a segment extending between a point on a sidewall of the support shield that is closest in the lateral direction to the trench shield and a point on a facing sidewall of the trench shield that is at a third depth from the upper surface of the semiconductor layer structure where the trench shield has a peak doping concentration defines an angle of at least 20°.

In some embodiments, the peak doping concentration of the trench shield and a peak doping concentration of the support shield differ by no more than a factor of three.

In some embodiments, a thickness of the trench shield is less than 0.3 microns.

In some embodiments, the peak doping concentration of the trench shield is at a depth of between 0.6 and 1.1 microns from the upper surface of the semiconductor layer structure.

In some embodiments, an upper portion of the drift region comprises a JFET region that has the first conductivity type and a peak doping concentration that is at least an order of magnitude greater than a peak doping concentration of a lower portion of the drift region. In some embodiments, a lowermost portion of the JFET region is at a fourth depth from the upper surface of the semiconductor layer structure that is deeper than a second depth that corresponds to a lowermost portion of the trench shield from the upper surface of the semiconductor layer structure. In some embodiments, a lowermost portion of the support shield is at a fifth depth from the upper surface of the semiconductor layer structure that is deeper than the fourth depth.

Pursuant to yet additional embodiments of the present invention, gate-controlled semiconductor devices are provided that comprise a semiconductor layer structure having an upper surface and a lower surface that are spaced apart from each other in a depth direction and a gate trench in the semiconductor layer structure. The semiconductor layer structure comprises a drift region that has a first conductivity type, a trench shield that has a second conductivity type, the trench shield underneath the gate trench, and a support shield that has the second conductivity type extending toward the lower surface of the semiconductor layer structure. A first depth from the upper surface of the semiconductor layer structure where the support shield has a peak doping concentration is at least 0.3 microns greater than a third depth from the upper surface of the semiconductor layer structure where the trench shield has a peak doping concentration.

In some embodiments, the third depth is less than 1.2 microns.

In some embodiments, the peak doping concentration of the trench shield is less than three times a peak doping concentration of the support shield.

In some embodiments, a thickness of the trench shield is less than 0.3 microns.

In some embodiments, the peak doping concentration of the trench shield is at a depth of between 0.6 and 1.1 microns from the upper surface of the semiconductor layer structure.

Pursuant to still other embodiments of the present invention, gate-controlled semiconductor devices are provided that comprise a semiconductor layer structure having an upper surface and a lower surface that are spaced apart from each other in a depth direction and a gate trench in the semiconductor layer structure. The semiconductor layer structure comprises a drift region that has a first conductivity type, a trench shield that has a second conductivity type, the trench shield underneath the gate trench, and a support shield that has the second conductivity type extending toward the lower surface of the semiconductor layer structure. A difference between a maximum depth of the support shield from the upper surface of the semiconductor layer structure and a maximum depth of the channel region from the upper surface of the semiconductor layer structure is more than five times a thickness of the trench shield in the depth direction.

In some embodiments, a peak doping concentration of the trench shield and a peak doping concentration of the support shield differ by no more than a factor of three.

In some embodiments, the thickness of the trench shield is less than 0.3 microns.

In some embodiments, a peak doping concentration of the trench shield is at a depth of between 0.6 and 1.1 microns from the upper surface of the semiconductor layer structure.

In some embodiments, the support shield has a peak doping concentration at a first depth from the upper surface of the semiconductor layer structure, wherein a lowermost portion of the trench shield is at a second depth from the upper surface of the semiconductor layer structure that is less than the first depth, and wherein the thickness of the trench shield is less than the first depth minus the second depth.

Pursuant to some embodiments of the present invention, gate-controlled semiconductor devices are provided that comprise a semiconductor layer structure comprising an upper surface and a lower surface that are spaced apart from each other by a depth direction and a gate trench in the semiconductor layer structure. The semiconductor layer structure comprises a drift region that has a first conductivity type, a well region that has a second conductivity type and comprises a channel region adjacent a sidewall of the gate trench, and a source region that has the first conductivity type on the well region. A lowermost portion of the source region is at a first depth from the upper surface of the semiconductor layer structure in the depth direction. A lower surface of the gate trench is at a second depth from the upper surface of the semiconductor layer structure in the depth direction. The second depth is between 0.6 and 0.8 microns deeper than the first depth.

In some embodiments, a thickness of the channel region in the depth direction is greater than a thickness of the source region in the depth direction.

In some embodiments, a thickness of the channel region in the depth direction is less than a thickness of the source region in the depth direction.

In some embodiments, the first depth is between 30% and 45% of the second depth, and a lowermost portion of the well region is at a third depth from the upper surface of the semiconductor layer structure in the depth direction that is greater than the first depth and less than the second depth.

In some embodiments, the third depth is between 0.4 and 0.6 microns deeper than the first depth.

In some embodiments, the third depth is between 0.2 and 0.4 microns deeper than the first depth.

In some embodiments, the second depth is between 1.0 and 1.2 microns.

Pursuant to further embodiments of the present invention, gate-controlled semiconductor devices are provided that comprise a semiconductor layer structure comprising an upper surface and a lower surface that are spaced apart from each other by a depth direction and a gate trench in the semiconductor layer structure. The semiconductor layer structure comprises a drift region that has a first conductivity type, a well region that has a second conductivity type and comprises a channel region adjacent a sidewall of the gate trench, and a source region that has the first conductivity type on the well region. A thickness of the channel region in the depth direction is less than a thickness of the source region in the depth direction.

In some embodiments, the thickness of the channel region is less than 0.5 microns.

In some embodiments, the thickness of the channel region is between 0.2 and 0.4 microns.

In some embodiments, the thickness of the channel region is between 50% and 95% of the thickness of the source region.

In some embodiments, a lowermost portion of the well region is at a first depth from the upper surface of the semiconductor layer structure in the depth direction, and a lower surface of the gate trench is at a second depth from the upper surface of the semiconductor layer structure in the depth direction that is greater than the first depth.

In some embodiments, the second depth is at least 0.3 microns deeper than the first depth.

In some embodiments, the second depth is between 0.3 and 0.5 microns deeper than the first depth.

In some embodiments, the first depth is between 55% and 70% of the second depth.

In some embodiments, the first depth is between 0.6 and 0.8 microns.

In some embodiments, the second depth is between 1.0 and 1.2 microns.

In some embodiments, the semiconductor layer structure further comprises a JFET region that has the first conductivity type in an upper portion of the drift region, the JFET region having a higher doping concentration than a doping concentration of a lower portion of the drift region, and a trench shield that has the second conductivity type underneath the gate trench. The first depth is at an interface between the lowermost portion of the well region and an uppermost portion of the JFET region, and the second depth is at an interface between the lower surface of the gate trench and an uppermost portion of the trench shield.

Pursuant to other embodiments of the present invention, gate-controlled semiconductor devices are provided that comprise a semiconductor layer structure comprising an upper surface and a lower surface that are spaced apart from each other by a depth direction and a gate trench in the semiconductor layer structure. The semiconductor layer structure comprises a drift region that has a first conductivity type, and a well region that has a second conductivity type and comprises a channel region adjacent a sidewall of the gate trench. A lowermost portion of the well region is at a first depth from the upper surface of the semiconductor layer structure in the depth direction. A lower surface of the gate trench is at a second depth from the upper surface of the semiconductor layer structure in the depth direction. A thickness of the channel region in the depth direction is less than a distance between the first depth and the second depth in the depth direction.

In some embodiments, the thickness of the channel region is between 50% and 95% of the distance between the first depth and the second depth.

In some embodiments, the thickness of the channel region is less than 0.5 microns.

In some embodiments, the distance between the first depth and the second depth is between 0.3 and 0.5 microns.

In some embodiments, the second depth is greater than the first depth.

Pursuant to still other embodiments of the present invention, gate-controlled semiconductor devices are provided that comprise a semiconductor layer structure comprising an upper surface and a lower surface that are spaced apart from each other by a depth direction and a gate trench in the semiconductor layer structure. The semiconductor layer structure comprises a drift region that has a first conductivity type, and a well region that has a second conductivity type and comprises a channel region adjacent a sidewall of the gate trench. A lowermost portion of the well region is at a first depth from the upper surface of the semiconductor layer structure in the depth direction. A lower surface of the gate trench is at a second depth from the upper surface of the semiconductor layer structure in the depth direction. The second depth is between 0.1 and 0.3 microns deeper than the first depth.

In some embodiments, the first depth is between 75% and 90% of the second depth.

In some embodiments, a distance between the first depth and the second depth in the depth direction is less than or equal to 50% of a thickness of the channel region in the depth direction.

In some embodiments, the semiconductor layer structure further comprises a JFET region that has the first conductivity type in an upper portion of the drift region, the JFET region having a higher doping concentration than a doping concentration of a lower portion of the drift region, and a trench shield that has the second conductivity type underneath the gate trench. The first depth is at an interface between the lowermost portion of the well region and an uppermost portion of the JFET region, and the second depth is at an interface between the lower surface of the gate trench and an uppermost portion of the trench shield.

In some embodiments, the gate-controlled semiconductor devices further comprise a source region that has the first conductivity type on the well region. A thickness of the channel region in the depth direction is greater than a thickness of the source region in the depth direction.

In some embodiments, the first depth is between 0.8 and 1.0 microns.

In some embodiments, the second depth is between 1.0 and 1.2 microns.

### BRIEF DESCRIPTION OF THE DRAWINGS

FIG. 1 is a semi-log graph illustrating the relationship between the lifetime of the gate oxide layer as a function of applied electric field strength.

FIG. 2A is a cross-sectional view of a unit cell of a conventional gate trench power MOSFET.

FIG. 2B is a graph illustrating the implanted doping concentrations as a function of depth in the semiconductor layer structure for various of the implanted regions in the unit cell of FIG. 2A.

FIG. 3A is a schematic top view of a gate trench silicon carbide power MOSFET according to certain embodiments of the present invention and also shows the bond wires that can be used to connect the gate and source pads to external circuits.

FIG. 3B is a schematic top view of the power MOSFET of FIG. 3A with an upper protective layer omitted to show the full gate and source metallization.

FIG. 3C is a schematic top view of the power MOSFET of FIG. 3A with the upper protective layer, the source metallization and an intermetal dielectric layer omitted to show the gate electrodes.

FIG. 3D is an enlarged view of the portion of FIG. 3C in the box labelled 3D.

FIG. 3E is a schematic cross-sectional view taken along line 3E-3E of FIG. 3D with the intermetal dielectric layer and source metallization that are omitted in FIGS. 3C-3D added for context.

FIG. 3F is an enlarged, non-schematic cross-sectional view of one of the unit cells shown in FIG. 3E that illustrates typical shapes of the implanted regions in an actual device.

FIG. 3G is a graph illustrating the implanted doping concentrations as a function of depth in the semiconductor layer structure for various of the implanted regions in the unit cell of FIG. 3F.

FIG. 3H is the cross-sectional view of FIG. 3F with additional labels added that highlight various features of the power semiconductor devices according to embodiments of the present invention that may enhance device performance.

FIG. 3I is a graph illustrating the doping concentrations and thickness (in the depth direction) of various of the implanted regions in a modified version of the power MOSFET of FIGS. 3A-3H.

FIG. 4 is a table illustrating unit cell designs for power MOSFETs according to further embodiments of the present invention.

FIG. 5A is a cross-sectional view of a unit cell of a power MOSFET according to further embodiments of the present invention.

FIG. 5B is a graph illustrating the relationship between the on-state resistance and the gate trench depth of the power MOSFET of FIG. 5A.

FIG. 6A is a cross-sectional view of a unit cell of a power MOSFET according to further embodiments of the present invention.

FIG. 6B is a graph illustrating the relationship between the on-state resistance and the gate trench depth of the power MOSFET of FIG. 6A.

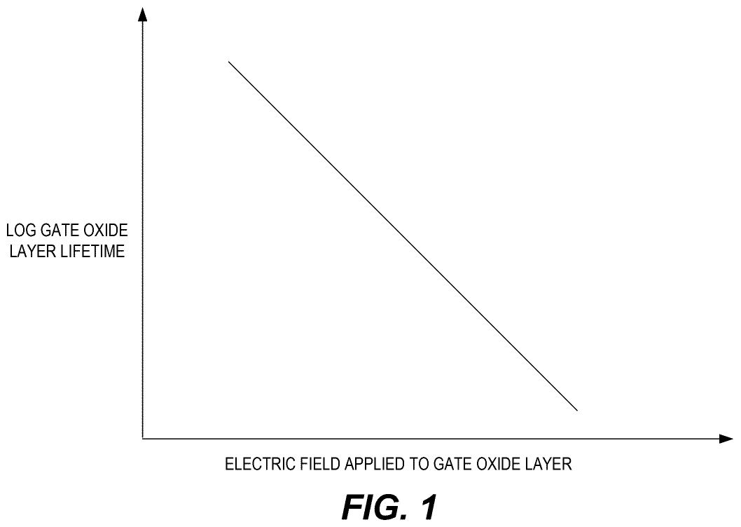

Two-part reference numerals that include two numbers separated by a dash (-) are sometimes used in the figures and the discussion that follows to identify instances of multiple like elements. The full reference number may be used to refer to individual instances of the like element while the first part of the reference number may be used to refer to the like elements collectively.

### DETAILED DESCRIPTION

Vertical silicon carbide based gate trench power semiconductor devices such as vertical power MOSFETs and IGBTs are attractive for many applications due to their inherent low specific on-resistance, which may result in more efficient operation for power switching operations. The channels in a gate trench vertical power device are formed in the sidewalls of the gate trenches, and hence are vertical channels. The carrier mobility in these vertically-oriented sidewall channels may be about 2-4 times higher than the corresponding carrier mobility in the horizontal channel of a standard planar gate (i.e., non-gate trench) vertical power device, which results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high frequency power applications having low to moderate voltage blocking requirements (e.g., 600-1200 Volts). These devices may have reduced requirements for associated passive components and require relatively simple cooling schemes. As MOSFETs are the most widely used silicon carbide based gate trench power semiconductor devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due to the presence of high electric fields in the gate oxide layers that line the bottoms and sidewalls of the gate trenches. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the lower surface of the semiconductor layer structure) toward the upper surface of the semiconductor layer structure. Thus, under reverse blocking operation, the bottom portion of the gate dielectric layer experiences the highest electric field levels. Due to electric field crowding effects, the electric field levels in the lower “corners” of the gate oxide layer at the bottom edges of the gate trench may be particularly high (i.e., the portions of the gate oxide layers that cover the region where the sidewalls of the gate trenches merge into the bottom of the gate trenches). Moreover, due to the difference in permittivity between silicon carbide and silicon oxide, the electric field in a silicon oxide gate oxide layer may be about 2.6 times higher than the electric field in the silicon carbide semiconductor layer structure adjacent the gate oxide layer. Breakdown of the silicon oxide occurs when the electric field reaches a critical level. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

So-called “trench shields” (also called “bottom shields”) are often provided underneath the gate trenches of gate trench power MOSFETs in order to reduce the electric field levels in the bottom portion of the gate oxide layer during reverse blocking operation. These trench shields are formed by doping the portions of the semiconductor layer structure underneath the gate trenches with dopants having the same conductivity type as the dopants included in the channel regions of the device. The trench shields are typically formed via one or more ion implantation processes in which p-type dopant ions (for an n-type MOSFET) are implanted through the bottom surfaces of the gate trenches. The trench shields may, for example, extend downwardly 0.5 to 1.0 microns or more from the bottoms of the gate trenches into the semiconductor layer structure of the device, and are moderately to highly doped regions. The trench shields are electrically connected to the source terminal of the MOSFET by p-type trench shield connection patterns. A variety of different trench shield connection patterns are known in the art, and any suitable trench shield connection pattern design may be used with the power semiconductor devices according to embodiments of the present invention.

Gate trench power MOSFETs may further include additional shielding regions that are referred to as “support shields.” The support shields are formed in the semiconductor layer structure between adjacent gate trenches and, like the trench shields, may comprise moderately or highly doped semiconductor regions having the same conductivity type as the channel regions of the MOSFET. The support shields may, for example, extend to the same depth in the semiconductor layer structure as the trench shields and may be formed by a high-energy ion implantation process. The support shields may directly connect to the source metallization in the active region of the device.

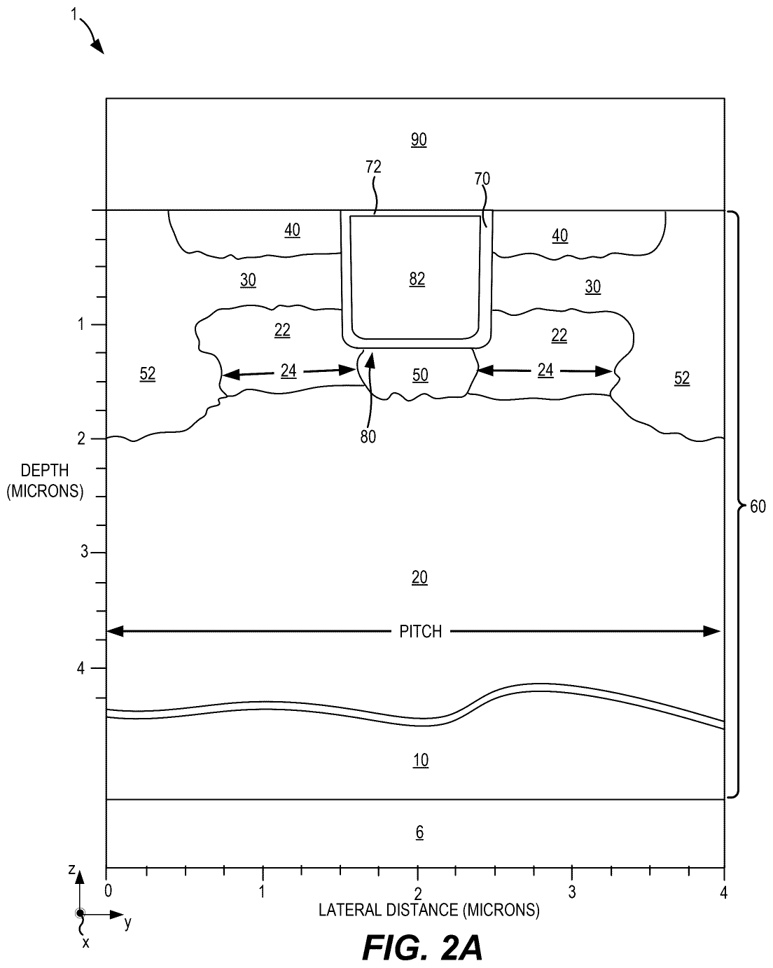

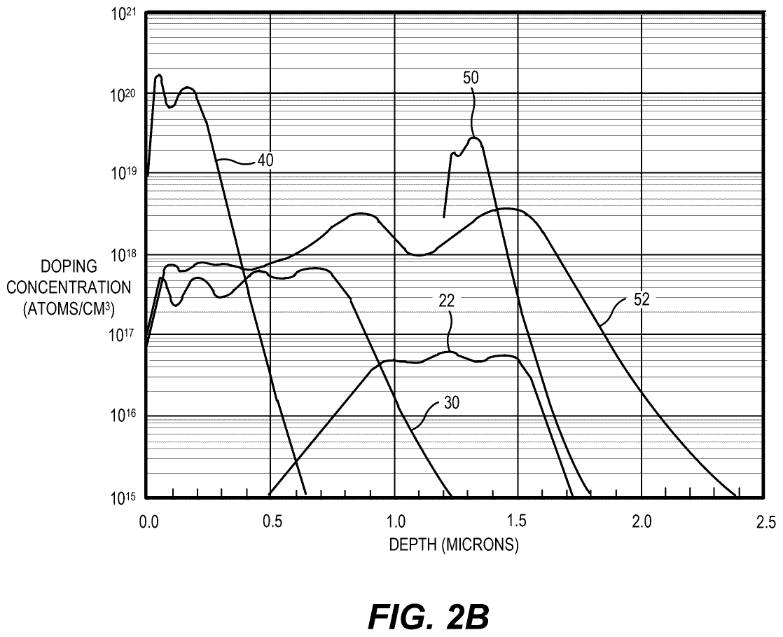

FIG. 2A is a cross-sectional view of a unit cell of a known silicon carbide power MOSFET 1 that includes support shields. The MOSFET 1 includes a semiconductor layer structure 60 that has first and second major surfaces that extend in the x-direction and the y-direction of an x-y-z coordinate system. The semiconductor layer structure 60 has a thickness in the z-direction, which is also referred to herein as the depth direction. The cross-sectional view of FIG. 2A is taken perpendicular to the x-direction. Thus, the vertical axis in FIG. 2A is the depth direction. The MOSFET 1 includes a plurality of gate trenches 80, which have longitudinal axes that run in the x-direction, so the y-direction in FIG. 2A is also referred to as the lateral direction, which is the width direction of the gate trenches 180.

As shown in FIG. 2A, the semiconductor layer structure 60 of MOSFET 1 includes a plurality of semiconductor layers and regions that have different conductivity types and doping concentrations. Some or all of these layers and regions may comprise silicon carbide layers/regions. As noted above, a plurality of gate trenches 80 are formed in the upper portion of the semiconductor layer structure 60. Only one gate trench 80 is shown in FIG. 2A since only a single unit cell is depicted.

The semiconductor layer structure 60 includes a silicon carbide semiconductor substrate 10. The silicon carbide semiconductor substrate 10 may be heavily-doped with n-type dopants. The semiconductor substrate 10 may be a thick layer (e.g., 50 microns or more) and hence only a very bottom portion of the semiconductor substrate 10 is shown in FIG. 2A. A lightly-doped n-type (n⁻) silicon carbide drift region 20 is provided on the upper surface of the substrate 10. The drift region 20 may also be a thick layer (e.g., several microns or tens of microns) and hence only a portion of the drift region 20 is shown in FIG. 2A. A plurality of n-type silicon carbide JFET regions 22 are formed in the upper portion of the drift region 20. The JFET regions 22 may be more heavily doped than the remainder of the drift region 20. The JFET regions 22 are typically formed by forming a continuous more heavily-doped (as compared to the remainder of the drift region 20) JFET layer via epitaxial growth. Subsequent ion implantation processes (discussed below) may then be performed to convert portions of the JFET layer into other regions to divide the JFET layer into the plurality of JFET regions 22.

Several different types of p-type regions are formed in the semiconductor layer structure 60 via ion implantation, including p-type wells 30 (also referred to as “p-wells”), p-type trench shields 50 and p-type support shields 52. The p-wells 30 may be moderately-doped p-type regions that are provided on the upper surfaces of the respective n-type JFET regions 22. The p-type trench shields 50 are relatively heavily doped p-type regions that are formed underneath the respective gate trenches 80, and may extend underneath the respective gate trenches 80 for all or substantially all of the length of each gate trench 80. Each p-type support shields 52 extend downwardly from an upper portion (e.g., the upper surface) of the semiconductor layer structure 60 in between a pair of adjacent gate trenches 80. The p-type support shields 52 may be moderately doped p-type silicon carbide regions. The gaps 24 that are defined between adjacent trench shields 50 and support shields 52 are referred to as “JFET gaps” 24, and may be formed in the JFET regions 22 and/or below the JFET regions 22, depending upon the design of the JFET regions 22. Finally, heavily-doped (n⁺) n-type silicon carbide source regions 40 are formed on upper portions of the p-wells 30, typically by ion implantation.

The substrate 10, drift region 20, JFET regions 22, p-wells 30, source regions 40, trench shields 50 and support shields 52 may form the semiconductor layer structure 60 of the MOSFET 1.

A gate oxide layer 70 is formed conformally within each gate trench 80, and gate electrodes 82 are formed in the respective gate trenches 80 on the gate oxide layers 70. An intermetal dielectric pattern 72 covers the gate electrodes 82. A source metallization 90 is formed on the intermetal dielectric pattern 72 and on the heavily-doped n-type source regions 40 and upper portions of the support shields 52. The source metallization 90 may include, for example, an ohmic contact layer (e.g., a metal silicide layer) that directly contacts the semiconductor layer structure 60, one or more adhesion layers, one or more diffusion barrier layers, one or more bulk metal layers and/or source pads. A metal drain contact 6 is formed on the lower surface of the substrate 10.

FIG. 2B is a graph illustrating the implanted doping concentration as a function of depth into the semiconductor layer structure 60 of various of the above-described regions of power MOSFET 1 that are formed by ion implantation. As shown in FIG. 2B, the source regions 40 are very heavily doped n-type, having a peak doping concentration that exceeds 1×10²⁰ dopants/cm³. The peak doping concentration occurs very near the uppermost surface of the semiconductor layer structure 60, and the doping concentration may decrease rapidly starting at a depth of about 0.2 microns into the semiconductor layer structure 60. The source regions 40 extend to a depth of nearly 0.4 microns into the semiconductor layer structure 60. Referring to FIG. 2A, it can be seen that the source regions 40 may be selectively implanted into the semiconductor layer structure 60 as opposed to being blanket implanted.

As is further shown in FIG. 2B, the p-wells 30 have a peak doping concentration of about 5×10¹⁷ dopants/cm³. While p-type dopants are implanted into the semiconductor layer structure 60 at a doping concentration of about 5×10¹⁷ dopants/cm³ from a depth of about 0.05 microns to a depth of about 0.7 microns, the much higher n-type doping concentration of the source regions 40 overwhelms the p-type dopants that are implanted to depths of less than about 0.4 microns, so that the uppermost surface of each p-well 30 is at a depth of about 0.4 microns. Each p-well 30 extends to a depth of about 0.9 microns, with the doping concentration of each p-well 30 decreasing rapidly from a depth of about 0.7 microns to the lowermost surface thereof. The ion implantation step used to form the p-wells 30 may be blanket implanted into the active region of power MOSFET 1.

Still referring to FIG. 2B, the support shields 52 may be formed using one or more high energy ion implantation steps. The support shields 52 may extend to the upper surface of the semiconductor layer structure 60. The upper portion of each support shield 52 may have a p-type doping concentration of about 5×10¹⁷ dopants/cm³. Lower portions of each support shield 52 may have higher doping concentrations (e.g., between about 1×10¹⁸ dopants/cm³ to 4×10¹⁸ dopants/cm³), with the peak doping concentration occurring at a depth of about 1.5 microns into the semiconductor layer structure 60. Each support shield 52 may extend to a depth of about 2.1 microns into the semiconductor layer structure 60.

The trench shields 50 are formed below the gate trenches 80. Since the gate trenches 80 have a depth of about 1.2 microns into the semiconductor layer structure 60, the uppermost portion of each trench shield 50 is at a depth of 1.2 microns. The trench shields 50 have a peak doping concentration of about 3×10¹⁹ dopants/cm³, and this peak doping concentration occurs at a depth of about 1.3 microns into the semiconductor layer structure 60. The doping concentration of each trench shield 50 drops off rapidly after peaking at 3×10¹⁹ dopants/cm³, and the trench shields 50 merge into the drift layer 20 at a depth of about 1.6 microns so that each trench shield 50 has a thickness of about 0.4 microns.

Finally, FIG. 2B shows that more heavily doped n-type JFET regions 22 are formed in the upper portion of the drift region 20 (the drift region 20 may have an n-type doping concentration as grown of, for example, about 1×10¹⁶ dopants/cm³ or 2×10¹⁶ dopants/cm³). The JFET regions 22 in this example are formed by ion implantation, and have a peak doping concentration of about 6×10¹⁶ dopants/cm³. The JFET regions 22 extend as stripes at depths between about 0.7 microns and about 1.6 microns into the semiconductor layer structure 60.

Note that the thickness in the depth direction (i.e., in the vertical direction in FIG. 2A) of a first doped region in a power MOSFET such as the power MOSFET 1 of FIG. 2A is determined based on the doping concentrations (of activated dopants) in the regions above and/or below the first doped region. For example, the bottom of the source region 40 of MOSFET 1 occurs at a depth of about 0.4 microns, which is the depth at which the doping concentration of the p-well 30 that is below the source region 40 exceeds the doping concentration of the source region 40. As another example, the bottoms of the JFET regions 22 are each at a depth of about 1.65 microns, which is the depth at which the doping concentration of the JFET implant falls below the doping concentration of the lower portion of the drift region 20 (which is the region underlying the JFET region 22). As yet another example, the bottom of the trench shield 50 occurs at a depth of about 1.6 microns, which is the depth at which the doping concentration of the trench shield 50 falls below the doping concentration of the lower portion of the drift region 20 (which is the region underlying the trench shield 50).

The p-type trench shields 50 and the p-type support shields 52 act to suppress the electric fields in the upper portion of the semiconductor layer structure 60 during reverse blocking operation, thereby lowering the electric fields in the gate oxide layers 70, which improves the reliability of MOSFET 1. Unfortunately, however, the addition of the support shields 52 increases the “pitch” of the MOSFET 1 (i.e., the distance between adjacent unit cells in the y-direction, which is the lateral distance between unit cells), since the support shields 52 are added to each unit cell of MOSFET 1. If the pitch is not increased, then the JFET gaps 24 are reduced in size, which acts to increase the on-state resistance of power MOSFET 1, which is undesirable. In particular, on-state power loss of a power MOSFET can be calculated as:

Power Loss=I²*R

In the above equation, “I” represents the on-state current and “R” is the resistance along the current path. The resistance and current levels vary throughout different regions of the device, so the power loss for each segment of the current path is determined and summed to calculate the total power loss during on-state operation. If no support shields 52 were provided, then the JFET gaps 24 would be the distances between adjacent trench shields 50. The provision of the support shields 52 greatly narrows the JFET gaps 24. As the on-state current flows through these narrower JFET gaps 24, the high levels of current (“I”) result in increased power losses. To bring the power losses to acceptable levels, the JFET gaps 24 are increased. However, this increases the pitch of the power MOSFET 1, which is undesirable, as this reduces the integration level of the MOSFET 1.

Pursuant to embodiments of the present invention, gate trench silicon carbide power MOSFETs (and other power semiconductor devices) are provided that have improved shielding designs. The power semiconductor devices according to some embodiments of the present invention increase the separation in the depth direction between the location where each trench shield has a maximum doping concentration and the location in the depth direction where adjacent support shields have a maximum doping concentrations. The power semiconductor devices according to other embodiments of the present invention increase the separation in the depth direction between the lowermost surface of each trench shield and the lowermost surface of the adjacent support shields. In each case, the revised configuration of the trench shields and support shields increases the size of the JFET gaps as compared to more conventional designs. This change advantageously decreases the on-state resistance of the power semiconductor devices and/or allows the pitch of the power semiconductor devices to be reduced while maintaining on-state resistance performance that is comparable to conventional power semiconductor devices.

Other aspects of the designs of the power semiconductor devices according to embodiments of the present invention may be revised to further improve performance. For example, the depth of the gate trenches may be reduced slightly to allow for greater separation between the lowermost surface of each trench shield and the lowermost surfaces of adjacent support shields. Likewise, the thickness of each trench shield may be reduced for the same reason, and/or the support shields may be formed to extend deeper than normal into the semiconductor layer structure. The peak doping concentration of the trench shields may be moved closer to the upper surfaces of the trench shields. In fact, in some embodiments, the peak doping concentration of each trench shield may be the uppermost surface thereof so that the doping concentration of each trench shield decreases with increasing depth into the semiconductor layer structure.

The doping concentration of each trench shield may also be reduced below conventional levels so that the peak doping concentration of the trench shield is, for example, within a factor of three of the peak doping concentration of an adjacent support shield. This approach is counterintuitive as a primary purpose of the trench shields and support shields is to protect the gate oxide layers that line the respective gate trenches. Since the trench shields are directly adjacent (and usually contacting) these gate oxide layers, increasing the doping concentration of the trench shields provides the biggest impact in terms of protection to the gate oxide layers during reverse blocking operation. The present invention is based, in part, on the realization that when the pitch of the unit cells is reduced, the deep support shields may perform the primary electric field blocking function during reverse bias operation, particularly when the support shields include “bulges” that extend toward the trench shields. By increasing the distance in the depth direction between the support shields and the trench shields, and/or by increasing the distance between the locations (depths) where the support shields and the trench shields have peak doping concentrations, more sharply angled JFET gaps may be created that are relatively wide even though the pitch of the device is reduced. Moreover, since the deep support shields serve the primary electric field blocking function, the doping concentration of the trench shields may be reduced, increasing the conductivity in the JFET gaps during on-state operation. In addition, the peak doping concentration and/or the depth of the JFET regions may be increased in the power semiconductor devices according to embodiments of the present invention in order to increase the conductivity of the upper portion of the drift region during on-state operation. This increased conductivity facilitates reducing the pitch of the unit cells without increasing on-state resistance.

One way of understanding how the power semiconductor devices according to certain embodiments of the present invention can maintain desired on-state resistance levels while having a reduced pitch is to consider the angles defined between the lower surface of the semiconductor layer structure and two imaginary segments that extend between the trench shield and an adjacent support shield. The first of these segments extends from a point on a sidewall of the support shield that is at a depth within the semiconductor layer structure where the support shield has its peak doping concentration and a point on a sidewall of the trench shield that is at a depth within the semiconductor layer structure where the trench shield has a peak doping concentration. This first segment may be designed to form an angle α with respect to the lower surface of the semiconductor layer structure of, for example, at least 20°, at least 25°, at least 30°,at least 35°, or at least 40°, whereas the same segment in conventional power semiconductor designs typically defines a smaller angle such as an angle of less than 15°. The second of these segments extends from a point on a sidewall of the support shield that is closest in the lateral direction (the y-direction) to the trench shield and the point on a sidewall of the trench shield that is at a depth within the semiconductor layer structure where the trench shield has its peak doping concentration. This second segment may be designed to form an angle β with respect to the lower surface of the semiconductor layer structure of at least 30°, at least 35°, or at least 40°, whereas the same segment in conventional power semiconductor designs typically defines an angle of 27° or less. Increasing these angles acts to increase the JFET gap, improving on-state performance.

Pursuant to further embodiments of the present invention, gate trench silicon carbide power MOSFETs (and other power semiconductor devices) are provided that improve the contribution of the JFET regions to the on-state resistance. The power semiconductor devices according to some embodiments of the present invention optimize the separation in the depth direction between the lower surface of each gate trench and the lowermost portion of each well region. The revised configuration of the gate trenches and the well regions optimizes the on-state resistance of the JFET regions, thereby advantageously decreasing the on-state resistance of the power semiconductor devices. The present invention is based, in part, on the realization that there is an optimized vertical separation (in the depth direction) between the bottoms of the well regions and the bottoms of the gate trenches to be able to advantageously decrease the on-state resistance of the power semiconductor devices.

Other aspects of the designs of the power semiconductor devices according to embodiments of the present invention may be revised to further improve performance. For example, the thickness (i.e., the depth) of the well regions may be reduced to allow for greater separation between the lower surface of each gate trench and the lowermost portion of each well region. Reducing the thickness of the well regions can mitigate variations in the on-state resistance of the power semiconductor devices as a function of gate trench depth, thereby allowing for greater flexibility in the design of the gate trenches. Further, reducing the thickness of the well regions may improve the on-state resistance of the JFET regions by increasing the JFET thickness, which advantageously decreases the on-state resistance of the power semiconductor devices.

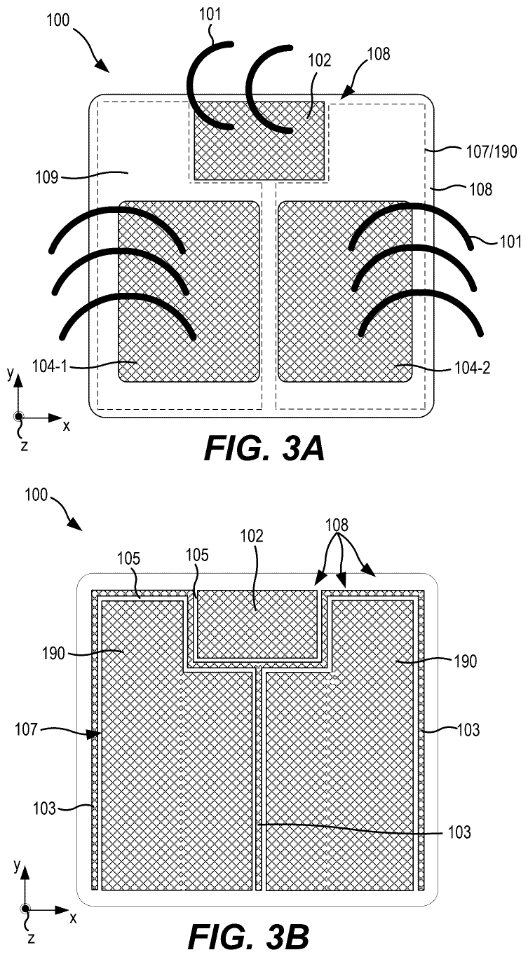

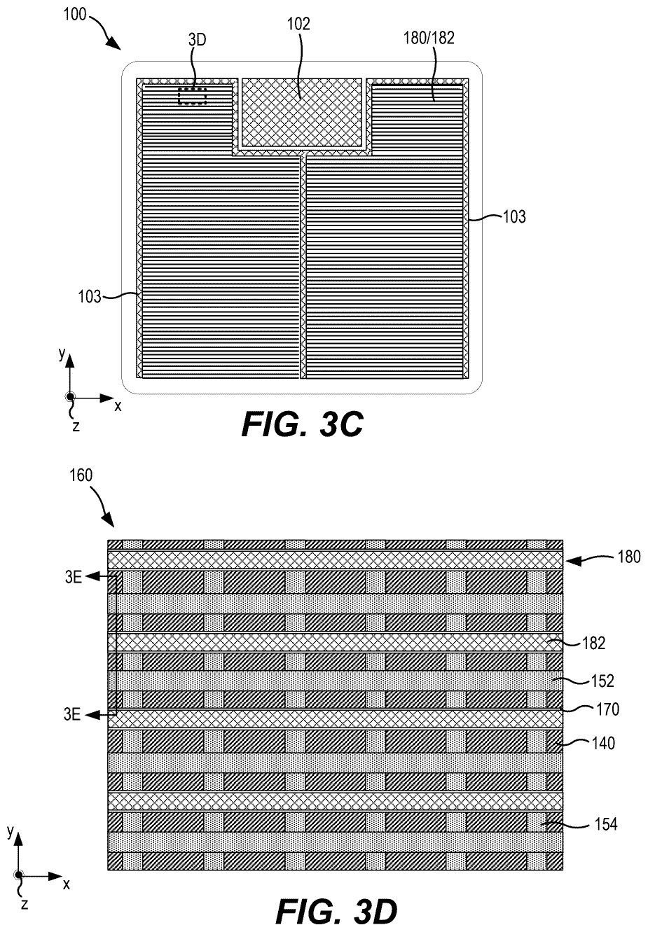

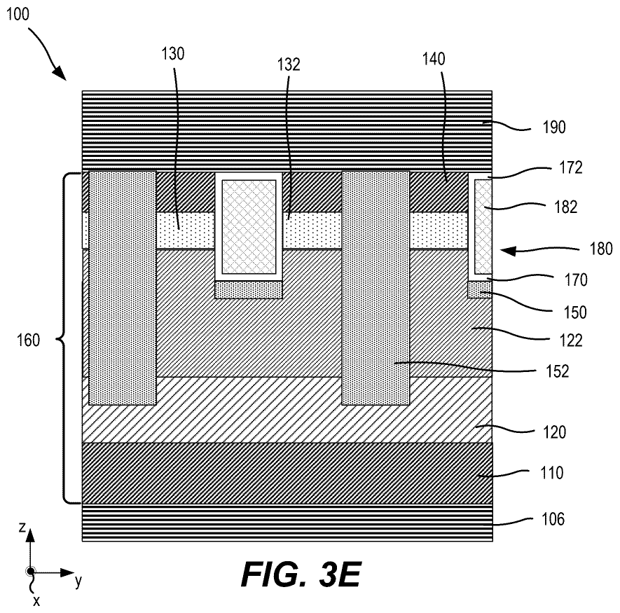

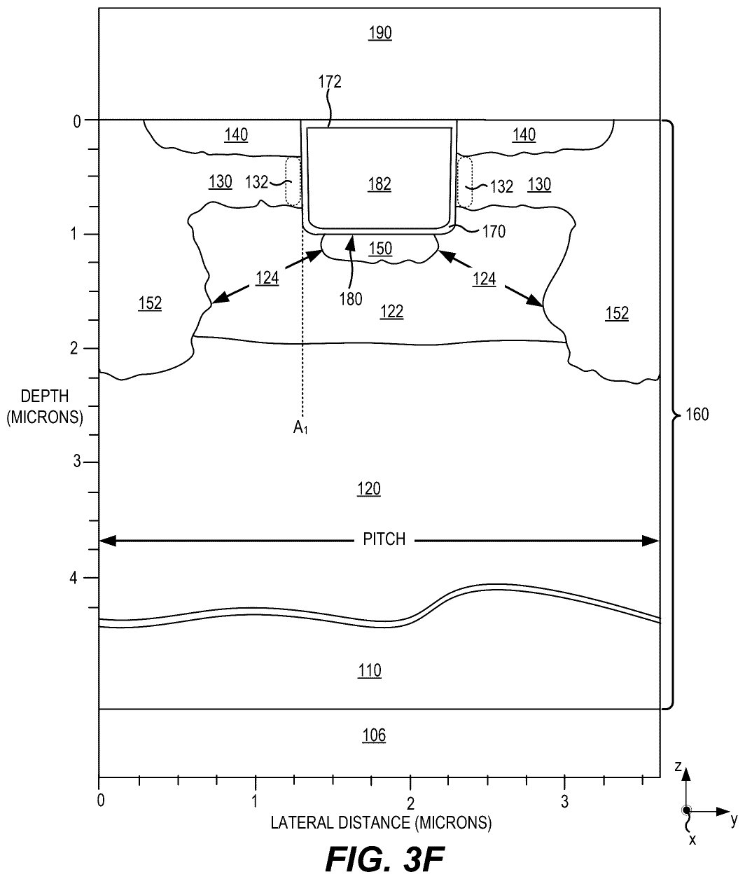

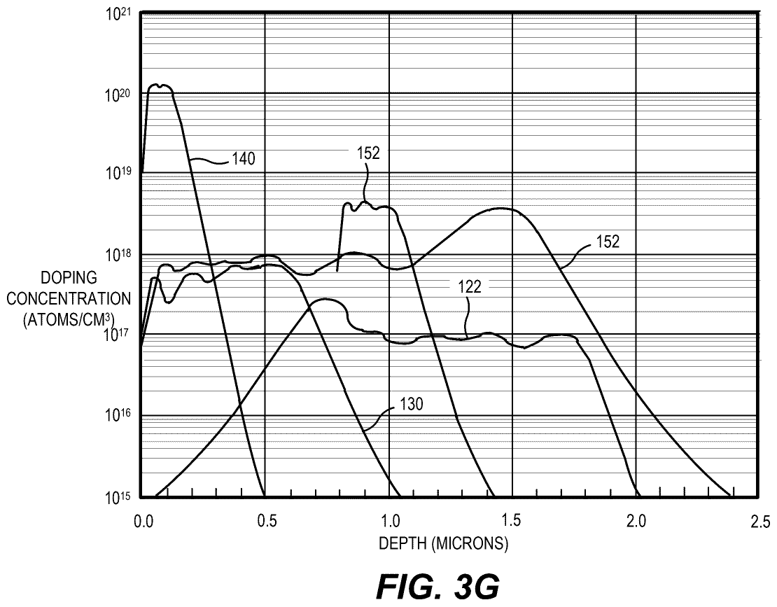

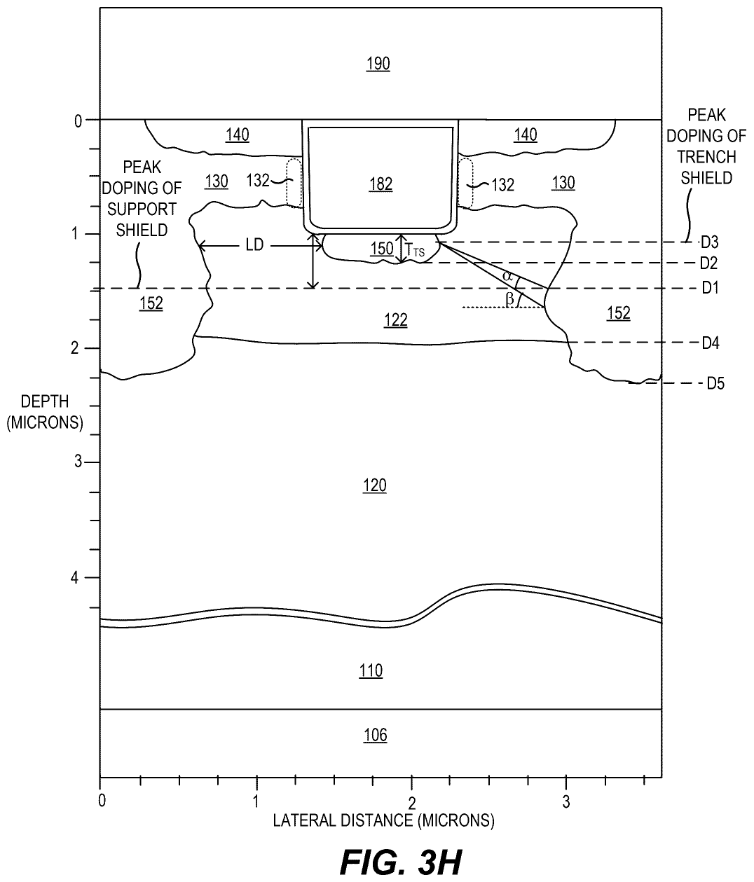

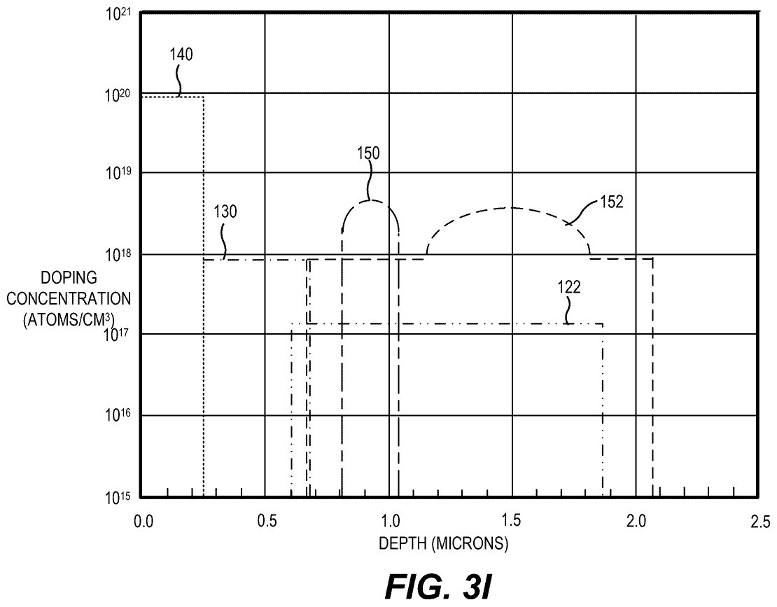

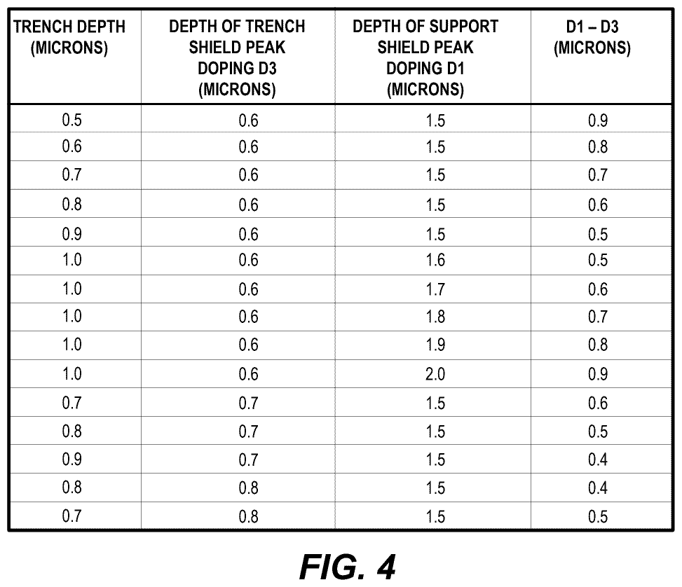

Embodiments of the present invention will now be described in more detail with reference to FIGS. 3A-3H and 4. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic top view of a gate trench silicon carbide power MOSFET 100 according to certain embodiments of the present invention. FIG. 3B is a schematic plan view of the power MOSFET 100 with an upper protective layer omitted to show the full gate and source metallization. FIG. 3C is a schematic top view of power MOSFET 100 with the upper protective layer, the source metallization and an intermetal dielectric layer omitted to show the gate electrodes. As will be discussed below with reference to various cross-sectional views, power MOSFET 100 includes a semiconductor layer structure 160 (sec FIGS. 3E-3F) that comprises a plurality of semiconductor layers/regions. At least one of the semiconductor layers in the semiconductor layer structure 160 may be a silicon carbide layer. Various metal and/or dielectric layers are formed on either side of the semiconductor layer structure 160 and embedded in the semiconductor layer structure 160.

Referring now to FIG. 3A, power MOSFET 100 includes a gate pad 102 and one or more source pads 104-1, 104-2 that are each formed on the upper side of the semiconductor layer structure 160. A metal drain pad 106 (see FIGS. 3E-3F) is provided on the bottom side of the semiconductor layer structure 160. The gate pad 102, the source pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 3A, the power MOSFET 100 includes a source

metallization 190 (indicated by the dashed boxes in FIG. 3A) that electrically connects certain regions of the semiconductor layer structure 160 to the source pads 104-1, 104-2. The source metallization 190 may include, for example, an ohmic contact layer (e.g., a metal silicide layer) that directly contacts the semiconductor layer structure 160, one or more adhesion and or barrier metal layers, one or more bulk metal layers and the source pads 104. Typically, the source pad 104 are a part of a bulk metal layer that is exposed through the protective layer 109. Herein, the source metallization 190 will be illustrated as a single layer for simplicity, but it will be appreciated that it typically includes multiple layers and may have any appropriate form. The source metallization 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions (discussed below).

Bond wires 101 are shown in FIG. 3A that may be used to connect the gate pad 102 and the source pads 104 to external circuits or the like. The drain pad 106 on the bottom side of power MOSFET 100 may be connected to an external circuit through, for example, an underlying submount (not shown).

FIG. 3B is another plan view of power MOSFET 100 with the polymide layer 109 omitted to expose the full source and gate metallization. As shown in FIG. 3B, the source metallization 190 extends throughout the active region 107 of the device. The gate metallization includes the gate pad 102 and a gate bus 103. The source metallization 190 is spaced apart from both the gate pad 102 and the gate bus 103 so that a single metal layer may be used to form the source metallization and the gate metallization. The gate pad 102 is spaced apart from the gate bus 103 so that the gate current may pass through one or more lumped gate resistors (not visible in the figures) that are formed underneath an intermetal dielectric layer 105. The lumped gate resistors may, for example, improve the electromagnetic interference (“EMI”) performance of the device and/or improve the stability of long feedback loops that are created as the lengths of the gate electrodes are increased in order to increase the power handling capability of the device. The metal gate buses 103 extend around much of the periphery of the active region 107. The gate buses 103 may provide a low resistance path for distributing gate signals that are applied to the gate pad to the gate electrodes 182 (see FIG. 3C) that extend throughout the active region 107.

FIG. 3C is the same view as FIG. 3B of power MOSFET 100 except that in FIG. 3C the source metallization 190 and the intermetal dielectric layer 105 are omitted to show the gate electrodes 182 that are formed in respective gate trenches 180 in the semiconductor layer structure 160. In the depicted MOSFET 100, the gate electrodes 182 extend horizontally across the semiconductor layer structure 160 (i.e., in the x-direction). In other cases, the gate electrodes 182 may extend vertically across the semiconductor layer structure 160, or both horizontally-extending and vertically-extending gate electrodes 182 can be provided to form a grid-like gate electrode structure. The gate electrodes 182 may be connected to the gate pad 102 through the gate buses 103. The gate electrodes 182 may comprise, for example, a doped polysilicon pattern.

FIG. 3D is an enlarged view of the portion of FIG. 3C in the box labelled 3D. FIG. 3E is a schematic cross-sectional view taken along line 3E-3E of FIG. 3D with an intermetal dielectric layer and source metallization 190 that are omitted in FIGS. 3C-3D added for context in FIG. 3E.

FIG. 3D is a plan view that illustrates the gate trenches 180, gate electrodes 182 and the upper surface of the semiconductor layer structure 160 in the active region 107 of power MOSFET 100. As can be seen in FIG. 3D, the gate trenches 180 are formed in the upper surface of the semiconductor layer structure 160. A longitudinal axis of each gate trench extends in the x-direction. A thin gate oxide layer 170, which is typically a silicon oxide layer, lines the sidewalls and bottom of each gate trench 180. A gate electrode 182, which is typically a highly-doped polysilicon gate electrode 182, is formed within each gate trench 180 on the gate oxide layer 170. The gate oxide layer 170 insulates the gate electrode 182 from the semiconductor layer structure 160. The gate trenches 180 (and hence the gate oxide layers 170 and gate electrodes 182) extend in parallel to each other in the x-direction. N-type source regions 140 arc formed in the upper surface of the semiconductor layer structure 160 on either side of each gate trench 180. P-type regions are formed midway in between adjacent gate trenches 180. In the depicted embodiment, the p-type regions comprise the upper surfaces of a plurality of support shields 152. In other embodiments, the p-type regions 152 may comprise separately implanted p-type contact regions or upper surfaces of a plurality of p-wells 130. While the p-type regions 152 are shown as longitudinal stripes of p-type material that extend in the same direction as the gate trenches 180 (i.e., the x-direction), it will be appreciated that embodiments of the present invention are not limited thereto. For example, in other embodiments, the p-type regions 152 may comprise “islands” of p-type material that are formed within a continuous source region 140 that extends between adjacent gate trenches 180. In other embodiments, the source regions 140 and the p-type regions 152 may comprise alternating stripes of n-type and p-type material, where these stripes extend in the y-direction.

As is further shown in FIG. 3D, a plurality of p-type trench shield connection patterns 154 extend in the y-direction. In the depicted embodiment, each p-type trench shield connection pattern 154 extends to the upper surface of the semiconductor layer structure 160, although embodiments of the present invention are not limited thereto. The p-type trench shield connection patterns 154 electrically connect a plurality of p-type trench shields 150 (see FIGS. 3E-3F) that are provided underneath the respective gate trenches 180 to the source metallization 190.

Referring next to the cross-sectional view of FIG. 3E, the unit cell structure of power MOSFET 100 is shown in more detail. As shown in FIG. 3E, power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n⁺ silicon carbide substrate). The impurities may comprise, for example, nitrogen or phosphorous. In example embodiments, the n-type substrate 110 may have a doping concentration of, for example, between 1×10¹⁸ atoms/cm³ and 1×10²¹ atoms/cm³, although other doping concentrations may be used. The substrate 110 may be relatively thick in some embodiments (e.g., 20-100 microns or more). The substrate 110 may be partially or fully removed in some embodiments. It should be noted that while the substrate 110 is depicted as a relatively thin layer, this is done to allow enlarging the thickness of other layers and regions in FIG. 3E, and it will be appreciated that the substrate 110 will typically be much thicker than shown.

A lightly-doped n-type (n−) silicon carbide drift layer 120 is provided on an upper surface of the substrate 110. The drift layer 120 may also be referred to herein as a drift region 120. Typically, the drift layer 120 is formed via an epitaxial growth process and is doped during growth. The n-type drift region 120 may have, for example, a doping concentration of 1×10¹⁴ to 5×10¹⁷ dopants/cm³, with the doping level typically selected based on a blocking voltage rating of the device. In the depicted embodiment, the n-type drift region 120 has a doping concentration of about 1×10¹⁶ dopants/cm³. The n-type drift region 120 may be a thick region, having a vertical height above the substrate 110 of, for example, 3-50 microns. An upper portion of the n-type drift region 120 may comprise an n-type JFET region 122 that is more heavily doped than the lower portion of the n-type drift region 120. The n-type JFET regions 122 are considered to be part of the drift region 120.

The drift layer 120 and the substrate 110 together act as a common drain region for the power MOSFET 100. The drain pad 106 is formed on the substrate 110 opposite the drift region 120.

A plurality of moderately-doped (p) p-type silicon carbide well regions 130 (which may also be referred to herein as a “p-wells 130”) are formed on the upper surface of the n-type JFET region 122. The moderately-doped (p) p-type silicon carbide well regions 130 may be formed either by epitaxial growth or, more typically, by implanting p-type dopant ions into the upper portion of the n-type drift region 120 to convert the upper portion of the n-type drift layer 120 into the p-type silicon carbide well regions 130. Channel regions 132 are provided in upper side portions of the p-wells 130 adjacent the gate trenches 180.

The above-discussed n-type source regions 140 are formed on upper portions of the respective p-wells 130. The source regions 140 are heavily-doped n-type (n+) silicon carbide source regions 140. The heavily-doped n-type silicon carbide source regions 140 may be formed by ion implantation.

As discussed above, a plurality of gate trenches 180 are formed in the upper surface of the semiconductor layer structure 160. P-type trench shields 150 are formed underneath the respective gate trenches 180. Each p-type trench shield 150 may, for example, extend underneath a respective one of the gate trenches 180 for all or substantially all of the length of the gate trench 180. The p-type trench shields 150 may be moderately doped (p⁺) silicon carbide regions.

As discussed herein, the p-type trench shields 150 in the power semiconductor devices according to embodiments of the present invention may be thinner in the depth direction and/or located closer to the upper surface of the semiconductor layer structure 160 than the trench shields in conventional MOSFET designs. For example, the lowermost portion of each trench shield 150 may be between 0.6 microns and 1.1 microns from the upper surface of the semiconductor layer structure 160. Typically, each trench shield 150 will extend to the same depth into the semiconductor layer structure 160 along its entire length and all of the trench shields 150 will extend to the same depth into the semiconductor layer structure 160. The p-type trench shields 150 may act to reduce the electric field levels that form in gate oxide layers 170 during device operation, as will be discussed in greater detail below.

A plurality of p-type support shields 152 are formed in the semiconductor layer structure 160. The support shields 152 extend significantly deeper into the semiconductor layer structure 160 than the trench shields 150. Each support shield 152 is positioned about midway in between a pair of adjacent gate trenches 180. While not shown in FIG. 3E, the width of each support shield 152 may vary as a function of depth (see FIG. 3F). Consequently, a lateral distance (i.e., a distance in the y-direction) between each support shield 152 and a facing trench shield 150 will vary with the depth of the support shield 152. The p-type trench shields 150 may be moderately doped (p⁺) silicon carbide regions.

The substrate 110, the drift region 120 (including the JFET regions 122), the p-wells 130 (including the channel regions 132), the source regions 140, the trench shields 150, the support shields 152 and the trench shield connection patterns 154 together comprise the semiconductor layer structure 160 of power MOSFET 100.

As noted above, a plurality of gate trenches 180 are formed in the upper portion of the semiconductor layer structure 160. While only one full gate trench 180 and a portion of a second gate trench 180 are shown in the cross-section of FIG. 3E, it will be appreciated from FIG. 3C that power MOSFET 100 may include a large number of gate trenches 180. The gate trenches 180 may be formed via an etching process.

A gate oxide layer 170 is provided in each gate trench 180 to cover the sidewalls and bottom surface of the gate trench 180. Each gate oxide layer 170 may comprise, for example, a silicon oxide (SiO₂) pattern. The gate oxide layers 170 may be formed generally conformally within the respective gate trenches 180.

A gate electrode 182 is formed in each gate trench 180 on the gate oxide layer 170. The gate electrodes 182 may comprise a conductive material such as a silicide (e.g., NiSi, TiSi, WSi, CoSi), a metal (e.g., Ti, Ta or W), a metal nitride (e.g., TiN, TaN or WN) or a doped semiconductor material (e.g., doped polycrystalline silicon). The gate oxide layers 170 may insulate the gate electrodes 182 from the semiconductor layer structure 160, thereby preventing the gate electrodes 182 from short circuiting to the semiconductor layer structure 160. Each gate electrode 182 may connect to one of the gate buses 103 (see FIGS. 3B-3C). In the depicted embodiment, the gate electrodes 182 are recessed so that the upper surface of each gate electrode 182 is below an upper surface of the semiconductor layer structure 160. It will be appreciated that in other embodiments the gate electrodes 182 may extend above and onto the upper surface of the semiconductor layer structure 160, with the gate oxide layer 170 insulating the gate electrodes 182 from the upper surface of the semiconductor layer structure 160.

Intermetal dielectric layers 172 are formed that cover each gate electrode 182. The intermetal dielectric layers 172 insulate the source metallization 190 from the gate electrodes 182.

The source metallization 190 is formed on the upper surface of the semiconductor layer structure 160 and on the intermetal dielectric layers 172. As discussed above, the source metallization 190 may comprise a single metal layer or multiple metal layers. Typically multiple metal layers are provided, as the source metallization 190 may include a single layer or multi-layer adhesion layer that contacts the semiconductor layer structure 160, one or more barrier layers, and a bulk metal layer (e.g., an aluminum layer).

FIG. 3F is an enlarged cross-sectional view of one of the unit cells shown in FIG. 3E.

As can be seen from FIG. 3F, the implanted regions may have non-vertical sidewalls (except where implanted regions border a sidewall of a gate trench 180) and portions of the implanted regions may have increased lateral (y-direction) widths. These phenomena may be most pronounced with respect to the support shields 152 since the support shields are the “thickest” implanted regions in the depth direction and hence may the most impacted by straggle. As shown, each support shield 152 may have a widened portion where the support shield 152 extends closer to a vertical axis A₁ that extends through the outermost portion of a sidewall of the trench shield 150 that faces the support shield 152. In other words, each support shield 152 has a bulge where the support shield 152 extends closer to the trench shield 150 along the y-direction. Each support shield 152 has a maximum depth in the semiconductor layer structure 160 of about 2.2 microns.

As shown in FIG. 3F, in one example embodiment, the gate trench 180 may only extend to a depth of 1.0 microns from the upper surface of the semiconductor layer structure 160. Consequently, as compared to conventional power MOSFET 1, the source region 140 of power MOSFET 100 has a reduced thickness (0.3 microns as opposed to 0.4 microns) as does the p-well 130 (0.4 microns as opposed to 0.5 microns). In addition, the trench shield 150 has a reduced thickness (0.2 microns as opposed to 0.4 microns). The support shields 152, on the other hand, extend slightly deeper into the semiconductor layer structure as compared to the support shields 52 of conventional power MOSFET 1. Finally, the pitch of power MOSFET 100 is reduced to 3.6 microns as compared to the 4.0 micron pitch of conventional power MOSFET 1 of FIG. 2A. As can be seen in FIG. 3F, the above design changes allow MOSFET 100 to have JFET gaps 124 that are comparable to the JFET gaps 24 of power MOSFET 1 even though power MOSFET 100 has a reduced pitch.

It will be appreciated that FIG. 3F illustrates one example embodiment of the present invention. In other embodiments, the gate trench 180 may have a depth of between 0.5 and 1.1 microns, between 0.6 and 1.0 microns, between 0.7 and 1.0 microns, or between 0.8 and 1.0 microns. The trench shield 150 has a thickness in the depth direction of about 0.2 microns in the embodiment shown in FIG. 3F. In other embodiments, the trench shield may have a thickness in the depth direction of less than 0.4 microns, less than 0.3 microns, less than 0.2 microns or even less than 0.1 microns. Likewise, the source regions 140 may have a thickness of between 0.1 and 0.5 microns, between 0.1 and 0.4 microns, or between 0.1 and 0.3 microns in other embodiments. The p-wells 130 may have a thickness of between 0.1 and 0.6 microns, between 0.2 and 0.5 microns, or between 0.3 and 0.5 microns in other embodiments. The maximum depth of the support shields 152 into the semiconductor layer structure 160 may be between 1.5 and 3.0 microns, between 1.8 and 2.8 microns, between 2.0 and 2.5 microns in other embodiments.

FIG. 3G is a graph illustrating the implanted doping concentrations as a function of depth in the semiconductor layer structure 160 for various of the implanted doped regions in the unit cell of the example embodiment of FIG. 3F. As shown in FIG. 3G, the source regions 140 are very heavily doped n-type, having a peak doping concentration that exceeds 1×10²⁰ dopants/cm³. In other embodiments, the source regions 140 may have a peak n-type doping concentration of between 1×10¹⁹ dopants/cm³ and 1×10²³ dopants/cm³. The source regions 140 are similar to the source regions 40 of the conventional power MOSFET 1 described above with reference to FIGS. 2A-2B, except that the source regions 140 are not quite as thick in the depth direction, namely they only extend 0.3 microns into the semiconductor layer structure 160, whereas the source regions 40 extend about 0.4 microns into the semiconductor layer structure 160. As discussed above, thinner source regions 140 (e.g., less than 0.25 microns thick) may be used in other embodiments. Any of the above ranges for peak doping concentration of the source regions 140 may be combined with any of the above ranges for the thickness of the source regions 140 in various embodiments.

As is further shown in FIG. 3G, the p-wells 130 have a peak doping concentration of about 8×10¹⁷ dopants/cm³. The p-wells 130 are similar to the p-wells 30 of the conventional power MOSFET 1 described above with reference to FIGS. 2A-2B, except that the p-wells 130 are slightly thinner in the depth direction (i.e., are 0.4 microns thick instead of 0.5 microns thick) and are formed slightly higher in the semiconductor layer structure 160 (i.e., p-wells 130 form a band of p-type material that extends between depths of 0.3 and 0.7 microns, whereas p-wells 30 form a band of p-type material that extends between depths of 0.4 and 0.9 microns). In other embodiments, the p-wells 130 may have a peak p-type doping concentration of between 1×10¹⁷ dopants/cm³ and 5×10¹⁹ dopants/cm³ or between 3×10¹⁷ dopants/cm³ and 6×10¹⁸ dopants/cm³ or between 6×10¹⁷ dopants/cm³ and 3×10¹⁸ dopants/cm³. Any of the above ranges for peak doping concentration of the p-wells 130 may be combined with any of the above ranges for the thickness of the p-wells 130 in various embodiments.

Still referring to FIG. 3G, the p-type support shields 152 have a peak p-type doping concentration of about 4×10¹⁸ dopants/cm³, with the peak doping concentration occurring at a depth of 1.5 microns into the semiconductor layer structure 160. The support shields 152 are similar to the support shields 52 of the conventional power MOSFET 1 described above with reference to FIGS. 2A-2B, except that the support shields 52 have a local doping concentration peak of about 3×10¹⁸ dopants/cm³ at a depth D1 (see FIG. 3H) of about 0.85 microns into the semiconductor layer structure 60, whereas this local peak is omitted in the support shields 152. Each support shield 152 extends to a depth D5 (sec FIG. 3H) of about 2.2 microns from the upper surface of the semiconductor layer structure 160. In other embodiments, the p-type support shields 152 may have a peak p-type doping concentration of between 6×10¹⁷ dopants/cm³ and 5×10¹⁹ dopants/cm³ or between 1×10¹⁸ dopants/cm³ and 1×10¹⁹ dopants/cm³ or between 2×10¹⁸ dopants/cm³ and 8×10¹⁸ dopants/cm³. In other embodiments, the support shields 152 may have peak doping concentrations that occur at a depth of between 1.2 and 2.0 microns into the semiconductor layer structure 160 or at a depth of between 1.4 and 2.0 microns into the semiconductor layer structure 160. Any of the above ranges for the location of the peak doping concentration of the support shields 152 may be combined with any of the above ranges for the maximum depth of the support shields 152 in various embodiments.

The size and doping concentration of the trench shields 150 vary more significantly from the size and doping concentration of the trench shields 50 of conventional power MOSFET 1. In particular, the thickness of the trench shields 150 is only about 0.2 microns thick, as compared to the trench shields 50 of power MOSFET 1, which are about twice as thick (i.e., a thickness of about 0.4 microns). As a result, the depth D3 (see FIG. 3H) where the peak doping concentration of each trench shield 150 occurs is shallower than in conventional power MOSFET 1. Moreover, the peak doping concentration of each trench shield 150 is about 3×10¹⁸ dopants/cm³, as compared to the peak doping concentration 3×10¹⁹ dopants/cm³ for the trench shields 50 of power MOSFET 1. In other words, the peak doping concentration of the trench shields 150 of power MOSFET 100 is reduced by an order of magnitude as compared to the peak doping concentration of the trench shields 50 of conventional power MOSFET 1. In addition, the peak doping concentration of the trench shields 150 may occur closer to an upper surface of the trench shields 150 (e.g., at a depth of less than 0.1 microns from the upper surface of the trench shield 150), whereas the peak doping concentration of each trench shield 50 of conventional power MOSFET 1 occurs at a depth that is more than 0.1 microns below the upper surface of each trench shields 50.

As is further shown in FIG. 3G, in one example embodiment, the depth within the semiconductor layer structure 160 where the support shield 152 has its maximum doping concentration is about 0.5 microns greater than the depth within the semiconductor layer structure 160 where the trench shield 150 has its maximum doping concentration. In other embodiments, the depth where the support shield 152 has its maximum doping concentration may be at least 0.3 microns, at least 0.4 microns, at least 0.5 microns, at least 0.6 microns or at least 0.7 microns greater than the depth where the trench shield 150 has its maximum doping concentration. In any of the above embodiments, the depth where the support shield 152 has its maximum doping concentration may be no more than 1.0 microns greater than the depth where the trench shield 150 has its maximum doping concentration.

Finally, FIG. 3G shows that the more heavily doped n-type JFET region 122 extends deeper into the semiconductor layer structure 160 (namely, to a depth D4 from the upper surface of the semiconductor layer structure 160 of about 1.9 microns, as shown in FIG. 3H) than the JFET region 22 of conventional power MOSFET 1 and JFET region 122 is also more heavily doped than the JFET region 22 of conventional power MOSFET 1. In particular, each JFET region 22 extends as a stripe at depth of 0.9-1.9 microns in the semiconductor layer structure 160 (whereas the JFET region 22 of conventional power MOSFET 1 only extends to a depth of about 1.6 microns), and has a doping concentration of about 1×10¹⁷ dopants/cm³, although the doping concentration is increased in the upper 0.2 microns of the JFET region 122 where a peak doping concentration of about 3×10¹⁷ dopants/cm³ occurs. In other embodiments, the JFET region 122 may have a maximum depth in the semiconductor layer structure 160 of between 1.4 to 2.5 microns, between 1.6 and 2.2 microns, or between 1.8 and 2.0 microns. In other embodiments, the JFET region 122 may have a peak doping concentration of between 6×10¹⁶ dopants/cm³ and 8×10¹⁷ dopants/cm³, between 8×10¹⁶ dopants/cm³ and 6×10¹⁷ dopants/cm³, or between 1×10¹⁷ dopants/cm³ and 5×10¹⁷ dopants/cm³. Any of the above ranges for peak doping concentration of the JFET region 122 may be combined with any of the above ranges for the maximum depth of the JFET region 122 in various embodiments.

FIG. 3H is a cross-sectional view of power MOSFET 100 that is identical to FIG. 3F, except that FIG. 3H highlights various features of the design of power MOSFET 100 that facilitate reducing the pitch of power MOSFET 100 as compared to power MOSFET 1 while providing similar or even improved performance.

Comparing FIGS. 3G and 3H to FIGS. 2A and 2B, it can be seen that power MOSFET 100 differs from conventional power MOSFET 1 in the following ways:

The depth of the gate trench 180 is reduced as compared to the depth of the gate trench 80 of power MOSFET 1. The shallower gate trench 180 also allows the lateral distance LD between the trench shield 150 and the inward “bulges” in the adjacent support shields 152 to be increased, thereby increasing the width of the JFET gaps 124.

The thickness T_{TS} of the trench shield 150 is reduced as compared to the thickness of the trench shield 50 of power MOSFET 1. The reduced thickness T_{TS} of the trench shield 150 allows the lateral distance LD between the trench shield 150 and the inward “bulges” in the adjacent support shields 152 to be increased, thereby increasing the width of the JFET gaps 124. As shown in FIG. 3H, due to the decreased depth of the gate trenches 180 and the reduced thicknesses T_{TS} of the trench shields 150, the lowermost surface of each trench shield 150 is at a second depth D2 that is about 1.2 microns from the upper surface of the semiconductor layer structure 160.

A third depth D3 where the peak doping concentration of the trench shield 150 occurs is moved closer to the top of the trench shield 150 (and, while not shown in FIG. 3H, may be at the upper surface of the trench shield 150 in other embodiments) as compared to the location of the peak doping concentration of the trench shield 50 of power MOSFET 1. This increases the conductivity of the JFET gap 124 during on-state operation as the locations where the trench shields 150 and the support shields 152 have their peak doping concentrations are moved further apart in the depth direction.

The peak doping concentration of the trench shield 150 is reduced (by about an order of magnitude) as compared to the peak doping concentration of the trench shield 50 of power MOSFET 1. The reduced peak doping concentration decreases the amount of straggle that occurs during the implantation, and hence increases the conductivity of the JFET gap 124 during on-state operation.

The thickness of each JFET region 122 is increased as compared to the thickness of the JFET region 22 of power MOSFET 1, since each JFET region 122 now extends to a fourth depth D4 of about 1.9 microns from the upper surface of the semiconductor layer structure 160. The increased thickness improves the conductivity of the device in the JFET gap 124 during on-state operation.

The peak doping concentration of the JFET region 122 is increased (by about a factor of five) as compared to the peak doping concentration of the JFET region 22 of power MOSFET 1. The increased peak doping concentration increases the conductivity of the device in the JFET gaps 124 during on-state operation.

As shown in FIG. 3H, the above changes increase two important angles that affect the size of the JFET gaps 124. In particular, the lower surface of the semiconductor layer structure 160 and a first segment that extends between a point on a sidewall of the support shield 152 that is closest in the lateral direction to the trench shield 150 (i.e., the point on the sidewall of the support shield that bulges the farthest toward the trench shield 150) and a point on a facing sidewall of the trench shield 150 that is at a third depth D3 from the upper surface of the semiconductor layer structure 160 where the trench shield 150 has a peak doping concentration defines an angle β of at least 20°. In addition, a second segment that extends between a point on a sidewall of the support shield 152 where the support shield has its peak doping concentration (i.e., the point on the sidewall of the support shield 152 that is at the first depth D1) and the point on the facing sidewall of the trench shield 150 that is at a third depth D3 from the upper surface of the semiconductor layer structure 160 where the trench shield 150 has a peak doping concentration defines an angle α of at least 35°.

As a result of these changes, the pitch of the power MOSFET 100 may be reduced by 10% as compared to conventional power MOSFET 1 while still providing equivalent performance. Notably, this improvement in the integration level of power MOSFET 100 is achieved without any additional processing steps or with any decrease in other performance parameters.

FIG. 3I is a graph illustrating the doping concentrations and thickness (in the depth direction) of various of the implanted regions in a modified version of power MOSFET 100. As shown in FIG. 3I, the source regions 140 may have a doping concentration of about 1×10²⁰ dopants/cm³ and may have a thickness of between 0.2 and 0.3 microns. The p-wells 130 may have a doping concentration of about 1×10¹⁸ dopants/cm³ and may have a thickness of about 0.4 microns. The JFET region 122 may have a doping concentration of about 1×10¹⁷ dopants/cm³ and may have a thickness of between 1.2 and 1.3 microns. The trench shield 150 may have a peak doping concentration of about 5×10¹⁸ dopants/cm³ and may have a thickness of about 0.2 microns. The support shields 152 may have a peak doping concentration of about 4×10¹⁸ dopants/cm³ and may have a thickness of between 1.4 and 1.5 microns.

Referring to FIGS. 3A-3H, pursuant to embodiments of the present invention, a gate-controlled semiconductor device 100 is provided that comprises a semiconductor layer structure 160 having an upper surface and a lower surface that are spaced apart from each other in a depth direction and a gate trench 180 in the semiconductor layer structure 160. The semiconductor layer structure 160 comprises a drift region 120 that has a first conductivity type (n-type), a trench shield 150 that has a second conductivity type (p-type), and a support shield 152 that has the second conductivity type (p-type) extending toward the lower surface of the semiconductor layer structure 160. The trench shield 150 is underneath the gate trench 180.

In some embodiments, the support shield 152 may have a peak doping concentration at a first depth D1 from the upper surface of the semiconductor layer structure 160, a lowermost portion of the trench shield 150 is at a second depth D2 from the upper surface of the semiconductor layer structure 160 that is less than the first depth D1, and a thickness T_{TS} of the trench shield 150 in the depth direction is less than the first depth D1 minus the second depth D2 (i.e., T_{TS}<D1−D2). In example embodiments, the first depth D1 corresponding to the peak doping concentration of the support shield 152 may between 1.0 microns and 2.0 microns, or between 1.2 microns and 1.8 microns, or between 1.4 microns and 1.6 microns. In example embodiments, the second depth D2 may be between 0.7 microns and 1.4 microns, or between 0.9 microns and 1.3 microns. In example embodiments, the thickness T_{TS} of the trench shield 150 may be between 0.1 microns and 0.4 microns or between 0.2 microns and 0.4 microns. In other embodiments, the thickness T_{TS} of the trench shield 150 may be less than 0.3 microns. In the specific example embodiment depicted in FIGS. 3A-3H, each support shield 152 has a peak doping concentration at a first depth D1 of about 1.5 microns, a lowermost portion of the trench shield 150 is at a second depth D2 of about 1.2 microns from the upper surface of the semiconductor layer structure 160, where the second depth D2 is less than the first depth D1, and a thickness T_{TS} of the trench shield 150 in the depth direction about 0.2 microns. As is readily apparent, T_{TS} (0.2 microns)<D1 (1.5 microns)−D2 (1.2 microns)=0.3 microns.

In other embodiments, the lower surface of the semiconductor layer structure 160 and a segment extending between a point on a sidewall of the support shield 152 that is at a first depth D1 from the upper surface of the semiconductor layer structure 160 where the support shield 152 has a peak doping concentration and a point on a facing sidewall of the trench shield 150 that is at a third depth D3 from the upper surface of the semiconductor layer structure 160 where the trench shield 150 has a peak doping concentration defines an angle β of at least 30°. A thickness T_{TS} of the trench shield 150 in the depth direction may be less than the first depth D1 minus the third depth D3 in some embodiments. The third depth D3 where the trench shield 150 has its peak doping concentration may be at a depth of between 0.6 and 1.1 microns from the upper surface of the semiconductor layer structure 160 in some embodiments.

In still other embodiments, the upper portion of the drift region 120 comprises a JFET region 122 that has a higher doping concentration than the lower portion of the drift region 120. In such embodiments, a lowermost portion of the JFET region 122 may be closer to the lower surface of the semiconductor layer structure 160 than a lowermost portion of the trench shield 150, and the support shield 152 may extend deeper into the semiconductor layer structure 160 than the JFET region 122. The peak doping concentration of the JFET region 122 may be at least an order of magnitude or at least two orders of magnitude greater than a peak doping concentration of the drift region 120. In some embodiments, a peak doping concentration of the trench shield 150 may be less than two orders of magnitude greater than the peak doping of the concentration of the JFET region 122. The lowermost portion of the JFET region 122 is at a fourth depth D4 from the upper surface of the semiconductor layer structure 160, and the fourth depth D4 may be deeper than the second depth D2. The lowermost portion of the support shield 152 is at a fifth depth D5 from the upper surface of the semiconductor layer structure 160. The fifth depth D5 may be deeper than the fourth depth D4.

In additional embodiments, a maximum depth D5 of the support shield 152 into the semiconductor layer structure 160 is more than three times greater than a minimum lateral distance between a sidewall of the trench shield 150 and a facing sidewall of the support shield 152. For example, in the embodiment of FIGS. 3A-3H, the maximum depth D5 of the support shield is about 2.1 microns and the minimum lateral distance LD between a sidewall of the trench shield 150 and a facing sidewall of the support shield 152 is about 0.65 microns. Thus, the depth D5 is more than three times greater than the lateral distance LD.

In yet additional embodiments, the lower surface of the semiconductor layer structure 160 and a segment extending between a point on a sidewall of the support shield 152 that is closest in the lateral direction to the trench shield 150 and a point on a facing sidewall of the trench shield 150 that is at a third depth D3 from the upper surface of the semiconductor layer structure 160 where the trench shield 150 has a peak doping concentration defines an angle α of at least 20°.

In still other embodiments, a first depth D1 from the upper surface of the semiconductor layer structure 160 where the support shield 152 has a peak doping concentration is at least 0.3 microns greater than a third depth D3 from the upper surface of the semiconductor layer structure 160 where the trench shield 150 has a peak doping concentration. For example, in the embodiment of FIGS. 3A-3H, the first depth D1 is about 1.5 microns, and the third depth D3 is about 1.0 microns, such that the first depth D1 is more than 0.3 microns greater than the third depth D3.

In further embodiments, a difference between a maximum depth D5 of the support shield 152 from the upper surface of the semiconductor layer structure 160 and a maximum depth of the channel region 132 from the upper surface of the semiconductor layer structure 160 (which is the bottom of the dotted box showing the location of each channel region 132) is more than five times a thickness T_{TS} of the trench shield 150 in the depth direction. For example, in the embodiment of FIGS. 3A-3H, the maximum depth D5 of the support shield 152 is about 2.1 microns, whereas the maximum depth of the channel region (i.e., the portion of the p-well 130 adjacent the gate trench 180) is about 0.7 microns. Since the thickness of the trench shield 150 is only 0.2 microns, five times the thickness T_{TS} of the trench shield 150 (5*0.2 microns=1.0 microns) is less than 2.1 microns−0.7 microns=1.4 microns.

In still further embodiments, the trench shield 150 has a graded doping concentration with an upper surface of the trench shield 150 having the highest doping concentration and the doping concentration of the trench shield 150 decreasing with increasing depth from the upper surface of the trench shield 150. This can be accomplished by forming a preliminary trench shield via ion implantation before the gate trench 180 is formed, where a lower portion of the preliminary trench shield has a graded doping concentration that decreases with increasing depth. After the preliminary trench shield is formed, the gate trenches are then formed and during the gate trench formation process the upper portion of the preliminary trench shield is etched away to form the trench shield 150 so that the upper portion of the trench shield has the highest doping concentration.

In some embodiments, a peak doping concentration of the trench shield 150 and a peak doping concentration of the support shield 152 may differ by no more than a factor of three.

It will be appreciated that FIGS. 3A-3H illustrate one example power MOSFET 100 according to embodiments of the present invention. Many changes may be made to the design of power MOSFET 100 without departing from the scope of the present invention. For example, as discussed above, one aspect of the power semiconductor devices according to embodiments of the present invention that provides improved performance is that the difference in the depth of the location where the trench shield 150 exhibits its peak doping concentration and the location where the support shields 152 exhibit their peak doping concentrations is at least 0.4 microns. FIG. 4 is a table illustrating a wide variety of power MOSFETs that have different depths for the gate trenches and trench shields and support shields that have peak doping concentrations at different depths that achieve a difference of at least 0.4 microns in the depth direction between the locations where the trench shields and the support shields have their respective peak doping concentrations. The power MOSFET 100 of FIGS. 3A-3H could be modified to have any of the designs shown in FIG. 4.

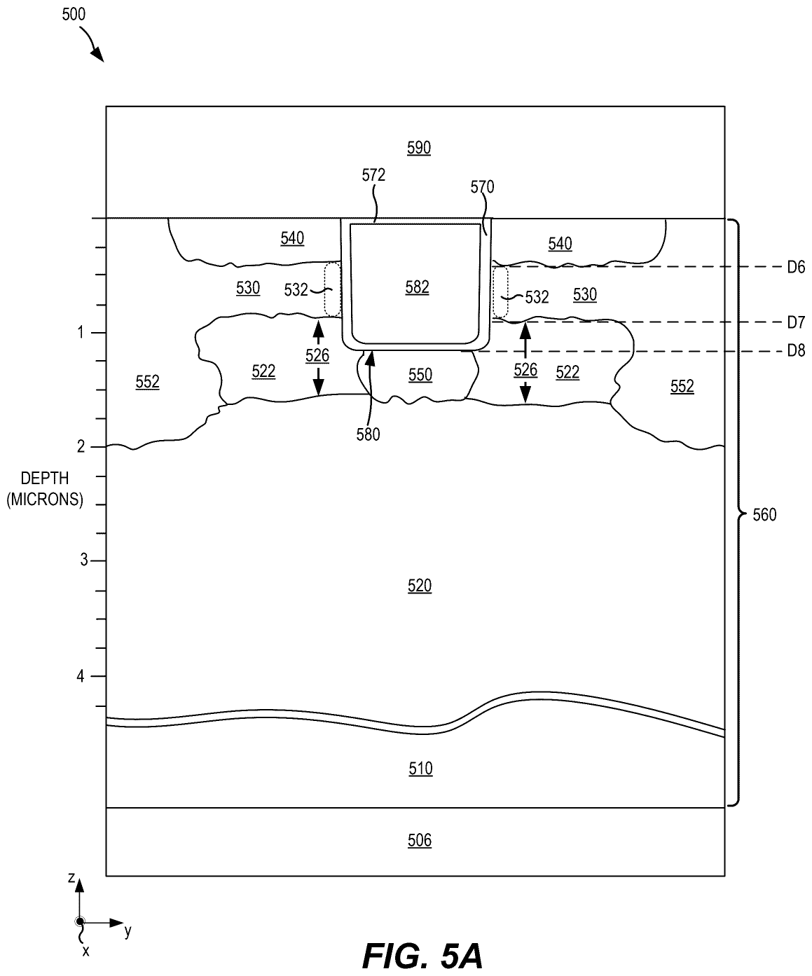

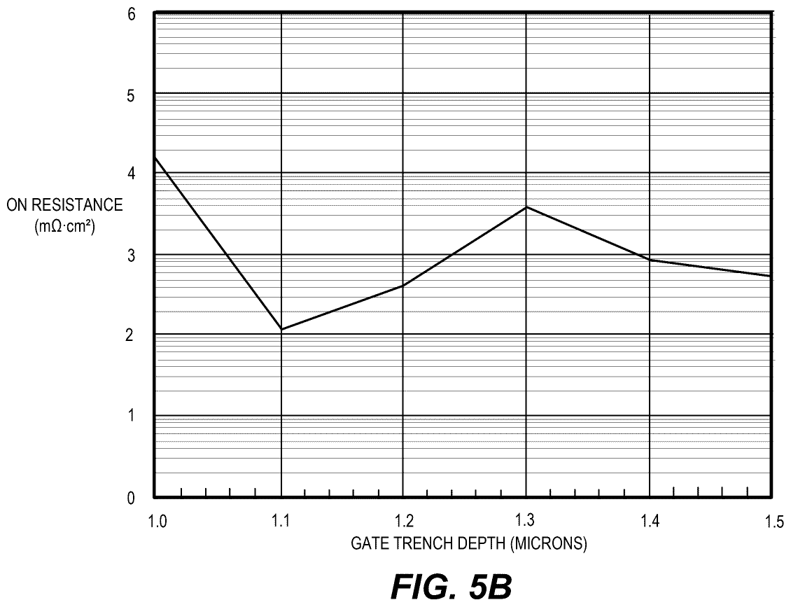

FIG. 5A is a cross-sectional view of a unit cell of a power MOSFET according to further embodiments of the present invention. As shown in FIG. 5A, the MOSFET 500 (which may also be referred to more generally as a gate-controlled semiconductor device) includes a semiconductor layer structure 560 that includes a plurality of semiconductor layers and regions that have different conductivity types and doping concentrations. Some or all of these layers and regions may comprise silicon carbide layers/regions. A plurality of gate trenches 580 are formed in the upper portion of the semiconductor layer structure 560. Only one gate trench 580 is shown in FIG. 5A since only a single unit cell is depicted. An upper surface and a lower surface of the semiconductor layer structure 560 may be spaced apart from each other by a depth direction (z-direction). For example, the depth direction (z-direction) may be taken in a direction substantially perpendicular to the upper surface of the semiconductor layer structure 560. While FIG. 5A illustrates a power MOSFET as an example, it will be appreciated that the same techniques used to improve the performance of the MOSFET 500 may be employed on any other gate-controlled semiconductor device having a gate trench structure.

The semiconductor layer structure 560 includes a silicon carbide semiconductor substrate 510. The silicon carbide semiconductor substrate 510 may be heavily-doped with n- type dopants. The semiconductor substrate 510 may be a thick layer (e.g., 50 microns or more) and hence only a very bottom portion of the semiconductor substrate 510 is shown in FIG. 5A. The semiconductor substrate 510 may have a doping concentration of, for example, between 1×10¹⁸ and 1×10²¹ atoms/cm³, although other doping concentrations may be used. A lightly-doped n-type (n⁻) silicon carbide drift region 520 is provided on the upper surface of the substrate 510. The drift region 520 may also be a thick layer (e.g., several microns or tens of microns) and hence only a portion of the drift region 520 is shown in FIG. 5A. The drift region 520 may have, for example, a doping concentration between 5×10¹⁵ to 5×10¹⁷ atoms/cm³.

A plurality of n-type silicon carbide JFET regions 522 are formed in the upper portion of the drift region 520. In some embodiments, the JFET regions 522 may be more heavily doped than the remainder of the drift region 520. That is, the JFET regions 522 may have a higher doping concentration than a doping concentration of a lower portion of the drift region 520. In some embodiments, the JFET regions 522 may be formed by forming a continuous more heavily-doped (as compared to the remainder of the drift region 520) JFET layer via epitaxial growth. Subsequent ion implantation processes (discussed below) may then be performed to convert portions of the JFET layer into other regions (e.g., support shields 552 and trench shields 550) to divide the JFET layer into the plurality of JFET regions 522.

Several different types of p-type regions are formed in the semiconductor layer structure 560 via ion implantation, including p-type wells 530 (also referred to as “p-wells” or “well regions”), p-type trench shields 550 and p-type support shields 552. The p-wells 530 may be moderately-doped p-type regions that are provided on the upper surfaces of the respective n-type JFET regions 522. The p-well 530 may be adjacent a sidewall of the gate trench 580. Channel regions 532 are provided in side portions of the p-wells 530 adjacent the gate trenches 580. That is, each p-well 530 may include a channel region 532 adjacent a sidewall of the gate trench 580.

The p-type trench shields 550 are relatively heavily doped p-type regions that are formed underneath the respective gate trenches 580, and may extend underneath the respective gate trenches 580 for all or substantially all of the length of each gate trench 580 (e.g., in the x-direction). The p-type support shields 552 may be moderately or heavily doped p-type silicon carbide regions. Each p-type support shield 552 extends downwardly from an upper portion (e.g., the upper surface) of the semiconductor layer structure 560 in between a pair of adjacent gate trenches 580.

The spacing 526 between the p-wells 530 and the drift region 520 may be referred to as the “JFET thickness” 526. Finally, heavily-doped (n⁺) n-type silicon carbide source regions 540 are formed on upper portions of the p-wells 530. In some embodiments, the source regions 540 may be formed by ion implantation.

The substrate 510, drift region 520, JFET regions 522, p-wells 530 (including the channel regions 532), source regions 540, trench shields 550 and support shields 552 may form the semiconductor layer structure 560 of the MOSFET 500.

A gate oxide layer 570 is formed conformally within each gate trench 580, and gate electrodes 582 are formed in the respective gate trenches 580 on the gate oxide layers 570. An intermetal dielectric pattern 572 covers the gate electrodes 582. A source metallization 590 is formed on the intermetal dielectric pattern 572 and on the heavily-doped n-type source regions 540 and upper portions of the support shields 552. The source metallization 590 may include, for example, an ohmic contact layer (e.g., a metal silicide layer) that directly contacts the semiconductor layer structure 560, one or more adhesion layers, one or more diffusion barrier layers, one or more bulk metal layers and/or source pads. A metal drain contact 506 is formed on the lower surface of the substrate 510.

The source regions 540 may be heavily doped n-type, having a doping concentration of, for example, between 1×10¹⁹ and 5×10²¹ atoms/cm³. The source regions 540 may extend to a depth D6 of about 0.3 microns to about 0.5 microns into the semiconductor layer structure 560, and may thus have a thickness in the depth direction (z-direction) of about 0.3 microns to about 0.5 microns. In other words, a lowermost portion (i.e., a lower surface) of each source region 540 may be at the depth D6 of about 0.3 microns to about 0.5 microns in the semiconductor layer structure 560. The depth D6 may be taken from the upper surface of the semiconductor layer structure 560 in the depth direction (z-direction). For example, the depth D6 may be at an interface between the lowermost portion of the source region 540 and an uppermost portion of the p-well 530. In some embodiments, the depth D6 may be about 0.4 microns into the semiconductor layer structure 560, and the source region 540 may thus have a thickness in the depth direction (z-direction) of about 0.4 microns, but the present disclosure is not limited thereto. As used herein, the thickness of the source region 540 refers to a maximum thickness of the source region 540 in the depth direction (z-direction). The source regions 540 may be selectively implanted into the semiconductor layer structure 560 as opposed to being blanket implanted.

The p-wells 530 may have a doping concentration of, for example, between 5×10¹⁶ to 1×10¹⁸ atoms/cm³. In some embodiments, p-type dopants may be implanted into the semiconductor layer structure 560 to form the p-wells 530. The higher n-type doping concentration of the source regions 540 may overwhelm the p-type dopants (i.e., may fully compensate the p-type dopants while leaving many uncompensated n-type dopants) that are implanted to depths of less than about 0.3 microns to about 0.5 microns, so that the uppermost portion (i.e., the upper surface) of each p-well 530 may be at the depth D6 of about 0.3 microns to about 0.5 microns in the semiconductor layer structure 560. In some embodiments, the depth D6 may be about 0.4 microns into the semiconductor layer structure 560, and the uppermost portion of each p-well 530 may thus be at a depth of about 0.4 microns in the semiconductor layer structure 560, but the present disclosure is not limited thereto.

Each p-well 530 may extend to a depth D7 of about 0.8 microns to about 1.0 microns in the semiconductor layer structure 560. In other words, a lowermost portion (i.e., a lower surface) of each p-well 530 may be at the depth D7 of about 0.8 microns to about 1.0 microns in the semiconductor layer structure 560. In some embodiments, the depth D7 may be about 0.4 microns to about 0.6 microns deeper than the depth D6. The depth D7 may be taken from the upper surface of the semiconductor layer structure 560 in the depth direction (z-direction). In some embodiments, the depth D7 may be about 0.9 microns in the semiconductor layer structure 560, but is not limited thereto. The doping concentration of each p-well 530 may decrease from a depth of about 0.6 microns to about 0.8 microns (e.g., 0.7 microns) to the lowermost portion thereof. Each p-well 530 (i.e., each channel region 532) may have a thickness in the depth direction (z-direction) of about 0.4 microns to about 0.6 microns. In some embodiments, each p-well 530 may have a thickness in the depth direction (z-direction) of about 0.5 microns, but is not limited thereto. As used herein, the thickness of the p-well 530 and the thickness of the channel region 532 refer to a maximum thickness of the channel region 532 in the depth direction (z-direction). It will be understood that the thickness of the p-well 530 as described herein is equivalent to the thickness of the channel region 532. In some embodiments, the p-well 530 may be thicker in the depth direction (z-direction) than the source region 540. That is, a thickness of the channel region 532 in the depth direction (z-direction) may be greater than a thickness of the source region 540 in the depth direction (z-direction). The ion implantation step used to form the p-wells 530 may be blanket implanted into the active region of the power MOSFET 500.

The support shields 552 may be formed using one or more high energy ion implantation steps. The support shields 552 may extend to the upper surface of the semiconductor layer structure 560. The support shields 552 may be moderately or heavily doped p-type silicon carbide regions. For example, each support shield 552 may have a doping concentration between about 5×10¹⁶ and 1×10²² atoms/cm³. In other embodiments, each support shield 552 may have a doping concentration between about 1×10¹⁸ and 1×10²⁰, between about 1×10¹⁹ and 1×10²⁰, between about 1×10¹⁷ and 1×10¹⁹, between about 1×10¹⁷ and 1×10²⁰, or between about 1×10¹⁸ and 1×10²¹ atoms/cm³. In some embodiments, the support shields 552 may have a doping concentration that is graded with depth. Each support shield 552 may extend to a depth of about 1.9 microns to about 2.1 microns (e.g., 2.0 microns) into the semiconductor layer structure 560, but is not limited thereto. In other embodiments, the depth of each support shield 552 may be between 1.0 and 3.0 microns, between 1.0 and 2.5 microns, between 1.5 and 3.0 microns, between 1.5 and 2.5 microns, or between 0.5 and 2.5 microns. Any of the above dopant concentration ranges for the support shields 552 may be matched with any of the above-listed depths for the support shields 552.

Each gate trench 580 may extend to a depth D8 of about 1.0 microns to about 1.2 microns into the semiconductor layer structure 560. In other words, a lower surface of each gate trench 580 may be at the depth D8 of about 1.0 microns to about 1.2 microns in the semiconductor layer structure 560. The depth D8 may be taken from the upper surface of the semiconductor layer structure 560 in the depth direction (z-direction). In some embodiments, the depth D8 may be about 1.1 microns in the semiconductor layer structure 560, but is not limited thereto.

The trench shields 550 are formed below the gate trenches 580. The uppermost portion of each trench shield 550 may be at the depth D8 of about 1.0 microns to about 1.2 microns in the semiconductor layer structure 560. For example, the depth D8 may be at an interface between a lower surface of the gate trench 580 and the uppermost portion (i.e., the upper surface) of the trench shield 550. Each trench shield 550 may have a doping concentration between, for example, 1×10¹⁶ and 1×10²² atoms/cm³. In other embodiments, each trench shield 550 may have a doping concentration between about 1×10¹⁸ and 1×10²⁰, between about 1×10¹⁹ and 1×10²⁰, between about 1×10¹⁷ and 1×10¹⁹, between about 1×10¹⁷ and 1×10²⁰, or between about 1×10¹⁸ and 1×10²¹ atoms/cm³. Each trench shield 550 may extend to a depth of about 1.2 microns to about 1.8 microns in the semiconductor layer structure 560. In other words, a lowermost portion of each trench shield 550 may be at a depth of about 1.2 microns to about 1.8 microns in the semiconductor layer structure 560. In some embodiments, each trench shield 550 may extend to a depth of about 1.5 microns in the semiconductor layer structure 560, but is not limited thereto. Each trench shield 550 may have a thickness in the depth direction (z-direction) of about 0.1 microns to about 0.7 microns. In some embodiments, each trench shield 550 may have a thickness in the depth direction (2-direction) of about 0.4 microns, but is not limited thereto. The trench shields 550 may be doped to have a higher doping concentration, a lower doping concentration, or approximately the same doping concentration as the support shields 552.

The JFET regions 522 may be formed by epitaxial growth and/or ion implantation, and may have a doping concentration between, for example, 5×10¹⁶ to 1×10¹⁸ atoms/cm³. An uppermost portion (i.e., an upper surface) of each JFET region 522 may be at a depth of about 0.8 microns to about 1.0 microns in the semiconductor layer structure 560. In some embodiments, the uppermost portion of each JFET region 522 may be at a depth of about 0.9 microns in the semiconductor layer structure 560, but is not limited thereto. For example, the uppermost portion of each JFET region 522 may be at the depth D7 in the semiconductor layer structure 560. The depth D7 may be at an interface between a lowermost portion of the p-well 530 and the uppermost portion of the JFET region 522.

As shown in FIG. 5A, each source region 540 may extend to the depth D6, each p-well 530 may extend to the depth D7, and each gate trench 580 may extend to the depth D8. The depth D7 may be greater than the depth D6 and less than the depth D8 in the depth direction (z-direction). The depth D6 of the source region 540, the depth D7 of the p-well 530, and the depth D8 of the gate trench 580 are selected to reduce the on-state resistance of the MOSFET 500. During forward bias (on-state) operation of the MOSFET 500, current flows through the JFET regions 522. A distance between the depth D7 and the depth D8 and between the depth D6 and the depth D8 may be selected to improve the contribution of the JFET regions 522 to the on-state resistance.

For example, depletion regions formed at the p-n junctions between p-type regions in the semiconductor layer structure 560 and the JFET region 522 may impact the on-state resistance of the MOSFET 500. As the gate trench 580 extends deeper into the semiconductor layer structure 560, farther away from the lowermost portion of the p-well 530, the distance between the p-well 530 and the trench shield 550 may increase. Increasing the distance between the p-well 530 and the trench shield 550 may help improve the on-state resistance of the MOSFET 500. However, as the gate trench 580 extends deeper into the semiconductor layer structure 560, a minimum distance between the trench shield 550 and the support shield 552 may decrease due to a phenomenon where the support shield 552 and/or the trench shield 550 increases in lateral width (in the y-direction) with increasing depth in the semiconductor layer structure 560 (sometimes referred to as “blooming” or “straggle”). As the distance between the trench shield 550 and the support shield 552 decreases, current flow in the JFET region 522 may become choked, increasing the on-state resistance of the MOSFET 500. If the gate trench 580 extends deep enough into the semiconductor layer structure 560, the negative effects of this phenomenon to the on-state resistance may be avoided, but protection offered by the support shield 552 to the gate oxide layer 570 during reverse blocking operation of the MOSFET 500 may be negatively impacted since the gate oxide layer 570 extends deeper into the semiconductor layer structure 560.

In example embodiments, the separation in the depth direction (z-direction) between the lower surface of each gate trench 580 and the lowermost portion of each p-well 530 (i.e., D8-D7) may be optimized to advantageously decrease the on-state resistance of the MOSFET 500. In addition, the separation in the depth direction (z-direction) between the lower surface of each gate trench 580 and the lowermost portion of each source region 540 (i.e., D8-D6) may be optimized to advantageously decrease the on-state resistance of the MOSFET 500. In some embodiments, the depth D8 may be between 0.1 microns and 0.3 microns deeper than the depth D7, and may be between 0.6 microns and 0.8 microns deeper than the depth D6. As shown in FIG. 5A, a distance between the depth D7 and the depth D8 in the depth direction (z-direction) may be less than the thickness of the p-well 530 (i.e., the thickness of the channel region 532) in the depth direction (z-direction). For example, a distance between the depth D7 and the depth D8 in the depth direction (z-direction) may be less than or equal to 50% of the thickness of the p-well 530 in the depth direction (z-direction). In some embodiments, the depth D7 may be between 75% and 90% of the depth D8. In other words, the depth D7 may be between 75% and 90% as deep as the depth D8. In some embodiments, the depth D6 may be between 30% and 45% of the depth D8. In other words, the depth D6 may be between 30% and 45% as deep as the depth D8. Accordingly, the separation in the depth direction (z-direction) between the p-well 530 and the gate trench 580 and between the source region 540 and the gate trench 580 may be optimized to advantageously decrease the on-state resistance of the MOSFET 500, without sacrificing the protection offered by the support shield 552 to the gate oxide layer 570 during reverse blocking operation.

FIG. 5B is a graph illustrating the relationship between the on-state resistance and the gate trench depth of the power MOSFET of FIG. 5A. P-wells 530 that extend to a depth D7 of about 0.9 microns were used in the simulation of FIG. 5B, but the present disclosure is not limited thereto.

Referring to FIGS. 5A and 5B, the on-state resistance (measured in milliohm square centimeters (mΩ·cm²)) of the MOSFET 500 may vary depending on the depth D8 of the gate trench 580 into the semiconductor layer structure 560. As shown in FIG. 5B, the on-state resistance of the MOSFET 500 may be lowest when the depth D8 of the gate trench 580 is between 1.0 micron and 1.2 microns. In other words, the on-state resistance of the MOSFET 500 may be lowest when the depth D8 of the gate trench 580 is between 0.1 microns and 0.3 microns deeper than the depth D7 of the p-well 530 and between 0.6 microns and 0.8 microns deeper than the depth D6 of the source region 540. In some embodiments, the on-state resistance of the MOSFET 500 may be lowest when the depth D8 of the gate trench 580 is about 1.1 microns (i.e., when the depth D8 of the gate trench 580 is about 0.2 microns deeper than the depth D7 of the p-well 530 and about 0.7 microns deeper than the depth D6 of the source region 540), but the present disclosure is not limited thereto. The on-state resistance of the MOSFET 500 may increase when the depth D8 of the gate trench 580 increases from 1.2 microns to 1.3 microns due to a distance between the trench shield 550 and the support shield 552 narrowing (e.g., in the y-direction). The on-state resistance of the MOSFET 500 may decrease when the depth D8 of the gate trench 580 increases beyond 1.3 microns, but protection offered by the support shield 552 to the gate oxide layer 570 during reverse blocking operation may be negatively impacted at these larger depths.

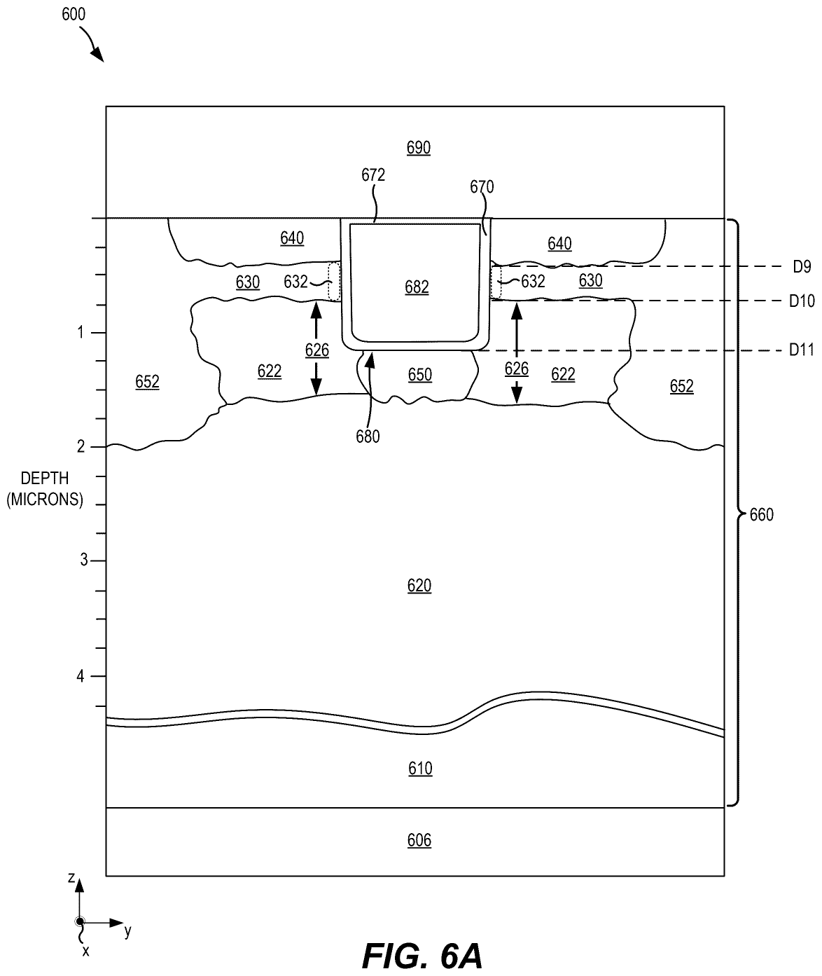

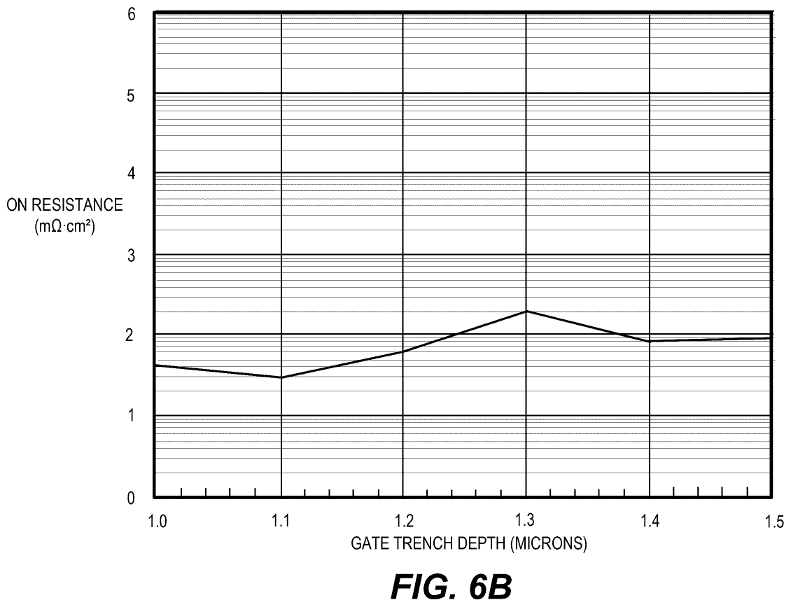

FIG. 6A is a cross-sectional view of a unit cell of a power MOSFET according to further embodiments of the present invention. The MOSFET 600 is similar to the MOSFET 500 described with reference to FIG. 5A, and thus the following description will mainly focus on the differences from the MOSFET 500 to avoid repeated description.

As shown in FIG. 6A, the MOSFET 600 includes a source region 640 that extends to a depth D9, a p-well 630 that extends to a depth D10, and a gate trench 680 that extends to a depth D11 in the semiconductor layer structure 660. In other words, a lowermost portion of the source region 640 may be at the depth D9 in the semiconductor layer structure 660, a lowermost portion of the p-well 630 may be at the depth D10 in the semiconductor layer structure 660, and a lower surface of the gate trench 680 may be at the depth D11 in the semiconductor layer structure 660. For example, the depth D9 may be at an interface between the lowermost portion of the source region 640 and an uppermost portion of the p-well 630, the depth D10 may be at an interface between the lowermost portion of the p-well 630 and an uppermost portion of the JFET region 622, and the depth D11 may be at an interface between the lower surface of the gate trench 680 and an uppermost portion of the trench shield 650.

The depth D10 of the p-well 630 may be shallower than the depth D7 of the p-well 530 described with reference to FIG. 5A. For example, the depth D10 may be about 0.6 microns to about 0.8 microns in the semiconductor layer structure 660. In other words, a lowermost portion of the p-well 630 may be at the depth D10 of about 0.6 microns to about 0.8 microns in the semiconductor layer structure 660. In some embodiments, the depth D10 of the p-well 630 may be about 0.7 microns in the semiconductor layer structure 660, but is not limited thereto. The depth D10 may be greater than the depth D9 and less than the depth D11. For example, the depth D10 may be between 0.2 microns and 0.4 microns deeper than the depth D9, and the depth D11 may be at least 0.3 microns deeper than the depth D10. The depths D9, D10, and D11 may be taken from the upper surface of the semiconductor layer structure 660 in the depth direction (z-direction).

A thickness of the p-well 630 in the depth direction (z-direction) may be less than the thickness of the p-well 530 in the depth direction (z-direction) described with reference to FIG. 5A. That is, a thickness of the channel region 632 in the depth direction (z-direction) may be less than the thickness of the channel region 532 in the depth direction (z-direction) described with reference to FIG. 5A. For example, the thickness of the p-well 630 (i.e., the channel region 632) may be less than 0.5 microns. In some embodiments, the thickness of the p-well 630 may be about 0.2 microns to about 0.4 microns. In some embodiments, the thickness of the p-well 630 may be about 0.3 microns, but is not limited thereto. As shown in FIG. 6A, the thickness of the p-well 630 in the depth direction (z-direction) may be less than the thickness of the source region 640 in the depth direction (z-direction). In other words, the channel region 632 may be thinner than the source region 640 in the depth direction (z-direction). For example, the thickness of the p-well 630 may be between 50% and 95% of the thickness of the source region 640.

The depth D9 of the source region 640 may be about 0.3 microns to about 0.5 microns in the semiconductor layer structure 660. In some embodiments, the depth D9 of the source region 640 may be about 0.4 microns, but is not limited thereto. The depth D11 of the gate trench 680 may be about 1.0 microns to about 1.2 microns in the semiconductor layer structure 660. In some embodiments, the depth D11 of the gate trench 680 may be about 1.1 microns, but is not limited thereto.

In some embodiments, the depth D11 may be between 0.3 microns and 0.5 microns deeper than the depth D10, and may be between 0.6 microns and 0.8 microns deeper than the depth D9. In some embodiments, the depth D10 may be between 55% and 70% of the depth D11. In other words, the depth D10 may be between 55% and 70% as deep as the depth D11. In some embodiments, the depth D9 may be between 30% and 45% of the depth D11. In other words, the depth D9 may be between 30% and 45% as deep as the depth D11. As shown in FIG. 6A, the thickness of the p-well 630 (i.e., the thickness of the channel region 632) in the depth direction (z-direction) may be less than a distance between the depth D10 and the depth D11 in the depth direction (z-direction). For example, the thickness of the p-well 630 in the depth direction (z-direction) may be between 50% and 95% of the distance between the depth D10 and the depth D11 in the depth direction (z-direction). In some embodiments, the distance between the depth D10 and the depth D11 in the depth direction (z-direction) may be between 0.3 microns and 0.5 microns.

Reducing the thickness (i.e., the depth) of the p-wells 630 may allow for greater separation between the lower surface of each gate trench 680 and the lowermost portion of each p-well 630, and hence the distance between the p-well 630 and the trench shield 650 may increase. Accordingly, reducing the thickness of the p-well 630 may mitigate variations in the on-state resistance of the MOSFET 600 as a function of the depth D11 of each gate trench 680. Further, reducing the thickness of the p-well 630 may improve the on-state resistance of the JFET regions 622 by increasing the thickness of the JFET regions 622, which advantageously decreases the on-state resistance of the MOSFET 600.

FIG. 6B is a graph illustrating the relationship between the on-state resistance and the gate trench depth of the power MOSFET of FIG. 6A. P-wells 630 that extend to a depth D10 of about 0.7 microns were used in the simulation of FIG. 6B, but the present disclosure is not limited thereto.

Referring to FIGS. 6A and 6B, the on-state resistance (measured in mΩ·cm²) of the MOSFET 600 may vary depending on the depth D11 of the gate trench 680 into the semiconductor layer structure 660. As shown in FIG. 6B, the on-state resistance of the MOSFET 600 may be lowest when the depth D11 of the gate trench 680 is between 1.0 microns and 1.2 microns. In other words, the on-state resistance of the MOSFET 600 may be lowest when the depth D11 of the gate trench 680 is between 0.3 microns and 0.5 microns deeper than the depth D10 of the p-well 630 and between 0.6 microns and 0.8 microns deeper than the depth D9 of the source region 640. In some embodiments, the on-state resistance of the MOSFET 600 may be lowest when the depth D11 of the gate trench 680 is about 1.1 microns (i.e., when the depth D11 of the gate trench 680 is about 0.4 microns deeper than the depth D10 of the p-well 630 and about 0.7 microns deeper than the depth D9 of the source region 640), but the present disclosure is not limited thereto. The on-state resistance of the MOSFET 600 may increase when the depth D11 of the gate trench 680 increases from 1.2 microns to 1.3 microns due to a distance between the trench shield 650 and the support shield 652 narrowing (e.g., in the y-direction). The on-state resistance of the MOSFET 600 may decrease when the depth D11 of the gate trench 680 increases beyond 1.3 microns, but protection offered by the support shield 652 to the gate oxide layer 670 during reverse blocking operation may be negatively impacted at these larger depths.

Referring to FIGS. 5B and 6B, it can be seen that reducing the thickness of the p-well 630 in the depth direction (z-direction) may mitigate variations in the on-state resistance of the MOSFET 600 as a function of gate trench depth when compared to the MOSFET 500. Further, reducing the thickness of the p-well 630 may advantageously decrease the on-state resistance of the MOSFET 600 beyond that of the MOSFET 500. Surprisingly, similar to the MOSFET 500, the on-state resistance of the MOSFET 600 may be lowest when the gate trench depth is about 1.1 microns, even though the thickness of the p-well 630 in the MOSFET 600 is reduced. This unexpected result leads to the p-well 630 (i.e., the channel region 632) having a thickness that is less than a thickness of the source region 640, such that the thickness of the p-well 630 in the depth direction (z-direction) is less than a distance between the depth D10 of the p-well 630 and the depth D11 of the gate trench 680 in the depth direction (z-direction).

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

References are made herein to a first element extending deeper into a semiconductor layer structure of a gate trench semiconductor device than a second element. The depth that an element extends into a semiconductor layer structure refers to a distance that the clement extends from an upper surface of the semiconductor layer structure, where the upper surface is the surface from which the gate trenches extend into the semiconductor layer structure. Thus, if a first element extends deeper into a semiconductor layer structure than a second clement, this means that a lowermost surface of the first element is farther from the upper surface of the semiconductor layer structure than is a lowermost surface of the second element.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10%.

As used herein, two elements of a semiconductor device are considered to “vertically overlap” if an axis that is perpendicular to the major surfaces of a semiconductor layer structure of the semiconductor device intersects both elements.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A gate-controlled semiconductor device, comprising:
a semiconductor layer structure comprising an upper surface and a lower surface that are spaced apart from each other by a depth direction; and
a gate trench in the semiconductor layer structure,
wherein the semiconductor layer structure comprises:
a drift region that has a first conductivity type;
a well region that has a second conductivity type and comprises a channel region adjacent a sidewall of the gate trench; and
a source region that has the first conductivity type on the well region,
wherein a lowermost portion of the source region is at a first depth from the upper surface of the semiconductor layer structure in the depth direction,
wherein a lower surface of the gate trench is at a second depth from the upper surface of the semiconductor layer structure in the depth direction, and
wherein the second depth is between 0.6 and 0.8 microns deeper than the first depth.

2. The gate-controlled semiconductor device of claim 1, wherein a thickness of the channel region in the depth direction is greater than a thickness of the source region in the depth direction.

3. The gate-controlled semiconductor device of claim 1, wherein a thickness of the channel region in the depth direction is less than a thickness of the source region in the depth direction.

4. The gate-controlled semiconductor device of claim 1, wherein the first depth is between 30% and 45% of the second depth, and
wherein a lowermost portion of the well region is at a third depth from the upper surface of the semiconductor layer structure in the depth direction that is greater than the first depth and less than the second depth.

5. The gate-controlled semiconductor device of claim 4, wherein the third depth is between 0.4 and 0.6 microns deeper than the first depth.

6. The gate-controlled semiconductor device of claim 4, wherein the third depth is between 0.2 and 0.4 microns deeper than the first depth.

7. The gate-controlled semiconductor device of claim 1, wherein the second depth is between 1.0 and 1.2 microns.

8. A gate-controlled semiconductor device, comprising:
a semiconductor layer structure comprising an upper surface and a lower surface that are spaced apart from each other by a depth direction; and
a gate trench in the semiconductor layer structure,
wherein the semiconductor layer structure comprises:
a drift region that has a first conductivity type;
a well region that has a second conductivity type and comprises a channel region adjacent a sidewall of the gate trench; and
a source region that has the first conductivity type on the well region, and
wherein a thickness of the channel region in the depth direction is less than a thickness of the source region in the depth direction.

9. The gate-controlled semiconductor device of claim 8, wherein the thickness of the channel region is less than 0.5 microns.

10. The gate-controlled semiconductor device of claim 9, wherein the thickness of the channel region is between 0.2 and 0.4 microns.

11. The gate-controlled semiconductor device of claim 8, wherein the thickness of the channel region is between 50% and 95% of the thickness of the source region.

12. The gate-controlled semiconductor device of claim 8, wherein a lowermost portion of the well region is at a first depth from the upper surface of the semiconductor layer structure in the depth direction, and
wherein a lower surface of the gate trench is at a second depth from the upper surface of the semiconductor layer structure in the depth direction that is greater than the first depth.

13. The gate-controlled semiconductor device of claim 12, wherein the second depth is at least 0.3 microns deeper than the first depth.

14. The gate-controlled semiconductor device of claim 13, wherein the second depth is between 0.3 and 0.5 microns deeper than the first depth.

15. The gate-controlled semiconductor device of claim 12, wherein the first depth is between 55% and 70% of the second depth.

16. The gate-controlled semiconductor device of claim 12, wherein the first depth is between 0.6 and 0.8 microns.

17. The gate-controlled semiconductor device of claim 16, wherein the second depth is between 1.0 and 1.2 microns.

18. The gate-controlled semiconductor device of claim 12, wherein the semiconductor layer structure further comprises:
a JFET region that has the first conductivity type in an upper portion of the drift region, the JFET region having a higher doping concentration than a doping concentration of a lower portion of the drift region; and
a trench shield that has the second conductivity type underneath the gate trench,
wherein the first depth is at an interface between the lowermost portion of the well region and an uppermost portion of the JFET region, and
wherein the second depth is at an interface between the lower surface of the gate trench and an uppermost portion of the trench shield.

19-23. (canceled)

24. A gate-controlled semiconductor device, comprising:
a semiconductor layer structure comprising an upper surface and a lower surface that are spaced apart from each other by a depth direction; and
a gate trench in the semiconductor layer structure,
wherein the semiconductor layer structure comprises:
a drift region that has a first conductivity type; and
a well region that has a second conductivity type and comprises a channel region adjacent a sidewall of the gate trench,
wherein a lowermost portion of the well region is at a first depth from the upper surface of the semiconductor layer structure in the depth direction,
wherein a lower surface of the gate trench is at a second depth from the upper surface of the semiconductor layer structure in the depth direction, and
wherein the second depth is between 0.1 and 0.3 microns deeper than the first depth.

25. The gate-controlled semiconductor device of claim 24, wherein the
first depth is between 75% and 90% of the second depth.

26. The gate-controlled semiconductor device of claim 24, wherein a distance between the first depth and the second depth in the depth direction is less than or equal to 50% of a thickness of the channel region in the depth direction.

27. The gate-controlled semiconductor device of claim 24, wherein the semiconductor layer structure further comprises:
a JFET region that has the first conductivity type in an upper portion of the drift region, the JFET region having a higher doping concentration than a doping concentration of a lower portion of the drift region; and
a trench shield that has the second conductivity type underneath the gate trench,
wherein the first depth is at an interface between the lowermost portion of the well region and an uppermost portion of the JFET region, and
wherein the second depth is at an interface between the lower surface of the gate trench and an uppermost portion of the trench shield.

28. The gate-controlled semiconductor device of claim 24, further comprising a source region that has the first conductivity type on the well region,
wherein a thickness of the channel region in the depth direction is greater than a thickness of the source region in the depth direction.

29. The gate-controlled semiconductor device of claim 24, wherein the first depth is between 0.8 and 1.0 microns.

30. The gate-controlled semiconductor device of claim 29, wherein the second depth is between 1.0 and 1.2 microns.

31. The gate-controlled semiconductor device of claim 8, wherein a lowermost portion of the well region is at a first depth from the upper surface of the semiconductor layer structure in the depth direction,
wherein a lower surface of the gate trench is at a second depth from the upper surface of the semiconductor layer structure in the depth direction, and
wherein the thickness of the channel region is less than a distance between the first depth and the second depth in the depth direction.
